(19) United States
(12) Patent Application Publication
(10) Pub. No.: US 2024/0372045 A1
(43) Pub. Date: Nov. 7, 2024

(54) DISPLAY DEVICE

(71) Applicant: Samsung Display Co., LTD., Yongin-si (KR)

(72) Inventors: Kyeong Woo JANG, Yongin-si (KR); Se Wan SON, Yongin-si (KR); Sung Ho KIM, Yongin-si (KR); Min Woo WOO, Yongin-si (KR); Seung Hyun LEE, Yongin-si (KR); Wang Woo LEE, Yongin-si (KR); Ji Seon LEE, Yongin-si (KR); Sug Woo JUNG, Yongin-si (KR); Hye Ri CHO, Yongin-si (KR)

(21) Appl. No.: 18/421,690

(22) Filed: Jan. 24, 2024

(30) Foreign Application Priority Data
May 4, 2023 (KR) 10-2023-0058243

(51) Int. Cl. H01L 33/54; H01L 25/075

(52) U.S. Cl. CPC H01L 33/54; H01L 25/0753

(57) ABSTRACT

A display device includes a substrate including a display area surrounded by a non-display area, a bank structure disposed on the substrate in the display area and including a plurality of openings, a plurality of light emitting elements disposed in the openings, a first dam disposed on the substrate in the non-display area and spaced apart from the bank structure, and a second dam spaced apart from the first dam in the non-display area, wherein the bank structure includes a first bank layer and a second bank layer disposed on the first bank layer, wherein the first dam includes a first sub-dam structure and a second sub-dam structure disposed on the first sub-dam structure, and the second bank layer includes tips protruding from sidewalls of the first bank layer, and the second sub-dam structure includes tips protruding from sidewalls of the first sub-dam structure.

This application claims priority from Korean Patent Application No. 10-2023-0058243, filed on May 4, 2023, and all the benefits accruing therefrom under 35 U.S.C. § 119, the content of which in its entirety is herein incorporated by reference.

### BACKGROUND

### 1. Field

The disclosure relates to a display device.

### 2. Description of the Related Art

As the information society develops, the demand for display devices for displaying images has increased and diversified. For example, display devices have been applied to various electronic devices such as smartphones, digital cameras, laptop computers, navigation devices, and smart televisions. The display devices may be flat panel display devices such as liquid crystal display devices, field emission display devices, or organic light emitting display devices. Among such flat panel display devices, a light emitting display device may display an image without a backlight unit providing light to a display panel because each of pixels of the display panel includes light emitting elements that may emit light by themselves.

### SUMMARY

Embodiments of the invention provide a display device including structures disposed at the outermost portions of a display area and a non-display area.

However, embodiments of the invention are not restricted to those set forth herein. The above and other aspects of the invention will become more apparent to one of ordinary skill in the art to which the invention pertains by referencing the detailed description of the invention given below.

A display device according to an embodiment may include dams having the same structure as a bank structure disposed in a display area and disposed in a non-display area. In the display device, even though an inorganic material layer disposed in the display area is used, the dams in the non-display area may have a sufficient height.

The effects of the disclosure are not limited to the aforementioned effects, and various other effects are included in the specification.

According to an embodiment of the disclosure, a display device includes a substrate including a display area and a non-display area surrounding the display area, a bank structure disposed on the substrate in the display area and including a plurality of openings, a plurality of light emitting elements disposed in the openings of the bank structure in the display area, a first dam disposed on the substrate in the non-display area and spaced apart from the bank structure, and a second dam spaced apart from the first dam in the non-display area, wherein the bank structure includes a first bank layer and a second bank layer disposed on the first bank layer and including a metal material different from that of the first bank layer, wherein the first dam includes a first sub-dam structure including the same material as the first bank layer and a second sub-dam structure disposed on the first sub-dam structure and including the same material as the second bank layer, and the second bank layer includes tips protruding from sidewalls of the first bank layer, and the second sub-dam structure includes tips protruding from sidewalls of the first sub-dam structure.

In an embodiment, the first dam may further include a first sub-dam, and the first sub-dam structure may be disposed on the first sub-dam.

In an embodiment, the first dam further may include an insulating pattern disposed on the first sub-dam and a spacer disposed on the second sub-dam structure, the insulating pattern may be disposed to surround the first sub-dam, and the spacer may be disposed to cover outer surfaces of the insulating pattern, the first sub-dam structure, and the second sub-dam structure.

In an embodiment, the second dam may include the same layers as the first sub-dam, the first sub-dam structure, and the second sub-dam structure, respectively, and the second dam may further include a second sub-dam disposed below the first sub-dam.

In an embodiment, the display device may further include a first via layer disposed between the bank structure and the substrate in the display area, and a second via layer disposed on the first via layer, wherein the first sub-dam may include the same material as the second via layer, and the second sub-dam may include the same material as the first via layer.

In an embodiment, the display area may include a first display area and a second display area surrounded by the first display area, and the display device may further include a hole dam disposed to surround the second display area.

In an embodiment, the hole dam may be spaced apart from the bank structure and include the first sub-dam structure and the second sub-dam structure.

In an embodiment, the display device may further include a bank connection part connecting the first dam and the bank structure to each other.

In an embodiment, the first dam may further include an insulating pattern, and the first sub-dam structure may be directly disposed on the insulating pattern.

In an embodiment, the display device may further include a third dam disposed to be spaced apart from the second dam, wherein the second dam may include a first sub-dam and a spacer disposed on the first sub-dam, and the third dam may include the first sub-dam, a second sub-dam disposed below the first sub-dam, and a spacer disposed on the first sub-dam.

In an embodiment, the first bank layer and the first sub-dam structure may include aluminum (Al), and the second bank layer and the second sub-dam structure may include titanium (Ti).

In an embodiment, the light emitting element may include an anode electrode disposed to overlap the opening, a light emitting layer disposed on the anode electrode, and a cathode electrode disposed on the light emitting layer, wherein the cathode electrode may be in contact with side surfaces of the first bank layer.

In an embodiment, the display device may further include an organic pattern disposed around the opening on the second bank layer and including the same material as the light emitting layer, an electrode pattern disposed on the organic pattern and including the same material as the cathode electrode, and an inorganic layer disposed to cover the light emitting element and the electrode pattern.

In an embodiment, the display device may further include a first power line disposed in the non-display area, wherein the first dam may be disposed on the first power line, and the bank structure is in contact with the first power line.

According to an embodiment, a display device includes a display area and a non-display area disposed around the display area, a bank structure disposed in the display area and including a plurality of openings in which a plurality of light emitting elements are disposed, a first dam disposed in the non-display area, spaced apart from the bank structure, and disposed to surround the bank structure, and a second dam spaced apart from the first dam in the non-display area and disposed to surround the first dam, wherein the bank structure includes a first bank layer and a second bank layer disposed on the first bank layer and including a metal material that is different from that of the first bank layer, wherein the first dam includes a dam structure including a first sub-dam structure including the same material as the first bank layer and a second sub-dam structure including the same material as the second bank layer and disposed on the first sub-dam structure, wherein the second bank layer includes tips protruding from sidewalls of the first bank layer, and the second sub-dam structure includes tips protruding from sidewalls of the first sub-dam structure.

In an embodiment, the first dam further may include a first sub-dam overlapping the dam structure, and the second dam may include the dam structure and the first sub-dam and may further include a second sub-dam overlapping the first sub-dam.

In an embodiment, each of the first dam and the second dam may further include an insulating pattern overlapping the first sub-dam and a spacer disposed on the dam structure.

In an embodiment, the display area may include a first display area and a second display area surrounded by the first display area, wherein the display device may further include a hole dam surrounding the second display area, disposed to be spaced apart from the bank structure, and including the dam structure.

In an embodiment, the second dam may include a first sub-dam, and the display device may further include a third dam disposed to be spaced apart from the second dam and to surround the second dam, and including the first sub-dam and a second sub-dam overlapping the first sub-dam.

In an embodiment, the first sub-dam of the second dam and the first sub-dam of the third dam may include the same material.

### BRIEF DESCRIPTION OF THE DRAWINGS

The above and other aspects and features of the invention will become more apparent and more readily appreciated from the following description of the embodiments, taken in conjunction with the accompanying drawings, in which:

FIG. 1 is a perspective view of an electronic device, according to an embodiment;

FIG. 2 is a perspective view illustrating a display device included in the electronic device, according to an embodiment;

FIG. 3 is a cross-sectional view of the display device of FIG. 2 as viewed from the side, according to an embodiment;

FIG. 4 is a schematic plan view illustrating a display layer of the display device, according to an embodiment;

FIG. 5 is a plan view illustrating arrangements of emission areas and color filters in a display area of the display device, according to an embodiment;

FIG. 6 is a cross-sectional view illustrating a portion of the display device, according to an embodiment;

FIG. 7 is an enlarged view illustrating a first emission area of FIG. 6, according to an embodiment;

FIG. 8 is a plan view illustrating an arrangement of a dam structure disposed in the display device, according to an embodiment;

FIG. 9 is an enlarged view of portion A of FIG. 8, according to an embodiment;

FIG. 10 is a cross-sectional view taken along line X-X′ of FIG. 9, according to an embodiment;

FIG. 11 is an enlarged view of portion B of FIG. 8, according to an embodiment;

FIG. 12 is a cross-sectional view taken along line XII-XII′ of FIG. 11, according to an embodiment;

FIG. 13 is a plan view illustrating an arrangement of a dam structure disposed in a display device, according to another embodiment;

FIG. 14 is an enlarged view of portion C of FIG. 13, according to an embodiment;

FIG. 15 is a cross-sectional view taken along line XV-XV′ of FIG. 14, according to an embodiment; and

FIG. 16 is a schematic view illustrating portions of a bank structure and a dam structure of a display device, according to another embodiment.

### DETAILED DESCRIPTION

The invention will now be described more fully hereinafter with reference to the accompanying drawings, in which preferred embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached drawing figures, the thickness of layers and regions may be exaggerated for clarity.

It will be understood that, although the terms “first,” “second,” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. For instance, a first element discussed below could be termed a second element without departing from the teachings of the invention. Similarly, the second element could also be termed the first element.

It will also be understood that when a layer is referred to as being “on” another layer or substrate, it can be directly on the other layer or substrate, or intervening layers may also be present. In contrast, when an element is referred to as being “directly on” another element, there are no intervening elements present.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” “At least one of A and B” means “A and/or B.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system).

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. A region illustrated or described as flat may, typically, have rough and/or nonlinear features, for example. Moreover, sharp angles that are illustrated may be rounded. Thus, the regions illustrated in the drawing figures are schematic in nature and their shapes are not intended to illustrate the precise shape of a region and are not intended to limit the scope of the claims.

Hereinafter, embodiments will be described with reference to the accompanying drawings.

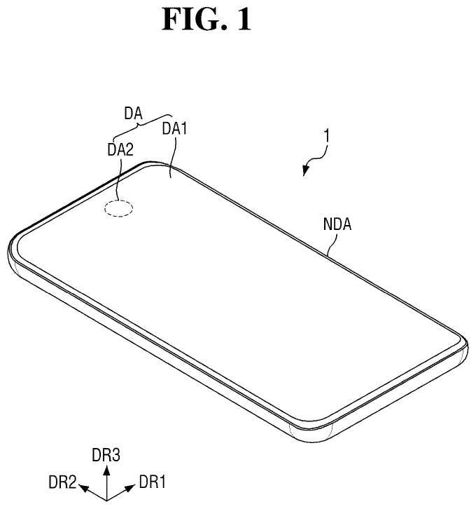

FIG. 1 is a perspective view of an electronic device, according to an embodiment.

In an embodiment and referring to FIG. 1, an electronic device 1 displays a moving image and/or a still image. The electronic device 1 may refer to all electronic devices that provide display screens. For example, televisions, laptop computers, monitors, billboards, the Internet of Things (IoT), mobile phones, smartphones, tablet personal computers (PCs), electronic watches, smart watches, watch phones, head mounted displays, mobile communication terminals, electronic notebooks, electronic books, portable multimedia players (PMPs), navigation devices, game machines, digital cameras, camcorders, and the like, which provide display screens, may be included in the electronic device 1.

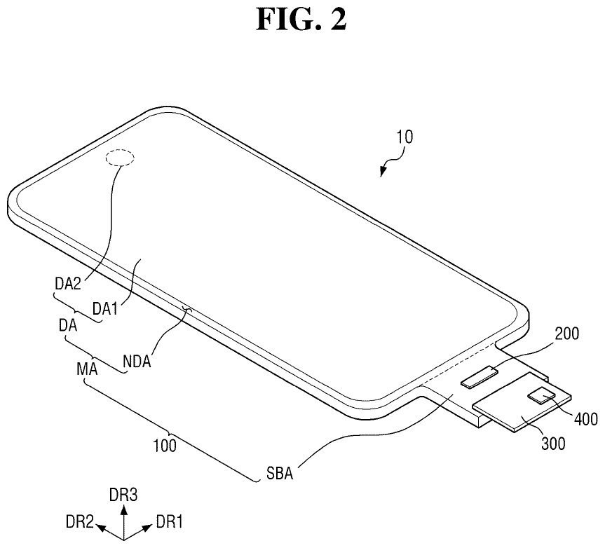

In an embodiment, the electronic device 1 may include a display device 10 (see FIG. 2) providing a display screen. Examples of the display device may include an inorganic light emitting diode display device, an organic light emitting display device, a quantum dot light emitting display device, a plasma display device, a field emission display device, and the like. Hereinafter, a case where an inorganic light emitting diode display device is applied as an example of the display device will be described by way of example, but the invention is not limited thereto, and the same technical scope may be applied to other display devices if applicable.

In an embodiment, a shape of the electronic device 1 may be variously modified. For example, the electronic device 1 may have a shape such as a rectangular shape with a width greater than a length, a rectangular shape with a length greater than a width, a square shape, a rectangular shape with rounded corners (vertices), other polygonal shapes, or a circular shape. A shape of a display area DA of the electronic device 1 may also be similar to an overall shape of the electronic device 1. In FIG. 1, the electronic device 1 having a rectangular shape with a great length in a second direction DR2 has been illustrated.

In an embodiment, the electronic device 1 may include a display area DA and a non-display area NDA. The display area DA is an area in which a screen may be displayed, and the non-display area NDA is an area in which a screen is not displayed. The display area DA may also be referred to as an active area, and the non-display area NDA may also be referred to as a non-active area. The display area DA may occupy substantially the center of the electronic device 1.

In an embodiment, the display area DA may include a first display area DA1 and a second display area DA2. The second display area DA2 is an area in which components for adding various functions to the electronic device 1 are disposed, and may correspond to a component area.

FIG. 2 is a perspective view illustrating a display device included in the electronic device 1, according to an embodiment.

Referring to FIG. 2, the electronic device 1, according to an embodiment, may include a display device 10. The display device 10 may provide a screen displayed by the electronic device 1. The display device 10 may have a shape similar to that of the electronic device 1 in a plan view. For example, the display device 10 may have a shape similar to a rectangular shape having short sides in a first direction DR1 and long sides in the second direction DR2. A corner where the short side in the first direction DR1 and the long side in the second direction DR2 meet may be rounded with a curvature, but is not limited thereto, and may also be right-angled. The shape of the display device 10 in a plan view is not limited to the rectangular shape, and may be a shape similar to other polygonal shapes, a circular shape, or an elliptical shape.

In an embodiment, the display device 10 may include a display panel 100, a display driver 200, a circuit board 300, and a touch driver 400.

In an embodiment, the display panel 100 may include a main area MA and a sub-area SBA.

In an embodiment, the main area MA may include a display area DA including pixels displaying an image and a non-display area NDA disposed around the display area DA. The display area DA may include a first display area DA1 and a second display area DA2. The display area DA may emit light from a plurality of emission areas and/or a plurality of opening areas. For example, the display panel 100 may include pixel circuits including switching elements, a pixel defining film defining the emission areas and/or the opening areas, and self-light emitting elements.

For example, in an embodiment, the self-light emitting elements may include at least one of an organic light emitting diode (LED) including an organic light emitting layer, a quantum dot LED including a quantum dot light emitting layer, an inorganic LED including an inorganic semiconductor, and a micro LED, but is not limited thereto.

In an embodiment, the non-display area NDA may be an area outside the display area DA. The non-display area NDA may be defined as an edge area of the main area MA of the display panel 100. The non-display area NDA may include a gate driver (not illustrated) supplying gate signals to gate lines, and/or fan-out lines (not illustrated) connecting the display driver 200 and the display area DA to each other.

In an embodiment, the sub-area SBA may be an area extending from one side of the main area MA. The sub-area SBA may include a flexible material that may be bent, folded, and/or rolled. For example, when the sub-area SBA is bent, the sub-area SBA may overlap the main area MA in a thickness direction (third direction DR3). The sub-area SBA may include the display driver 200 and pad parts connected to the circuit board 300. In another embodiment, the sub-area SBA may be omitted, and the display driver 200 and the pad parts may be disposed in the non-display area NDA.

In an embodiment, the display driver 200 may output signals and voltages for driving the display panel 100. The display driver 200 may supply data voltages to data lines. The display driver 200 may supply source voltages to power lines and supply gate control signals to the gate driver. The display driver 200 may be formed as an integrated circuit (IC) and may be mounted on the display panel 100 in a chip on glass (COG) manner, a chip on plastic (COP) manner, or an ultrasonic bonding manner. As an example, the display driver 200 may be disposed in the sub-area SBA, and may overlap the main area MA in the thickness direction by bending of the sub-area SBA. As another example, the display driver 200 may be mounted on the circuit board 300.

In an embodiment, the circuit board 300 may be attached onto the pad parts of the display panel 100 using an anisotropic conductive film (ACF). Lead lines of the circuit board 300 may be electrically connected to the pad parts of the display panel 100. The circuit board 300 may be a flexible printed circuit board, a printed circuit board, or a flexible film such as a chip on film.

In an embodiment, the touch driver 400 may be mounted on the circuit board 300. The touch driver 400 may be connected to a touch sensing unit of the display panel 100. The touch driver 400 may supply touch driving signals to a plurality of touch electrodes of the touch sensing unit and may sense change amounts in capacitance between the plurality of touch electrodes. For example, the touch driving signal may be a pulse signal having a predetermined frequency. The touch driver 400 may decide whether or not an input has occurred and calculate input coordinates, based on the change amounts in capacitance between the plurality of touch electrodes. The touch driver 400 may be formed as an integrated circuit (IC).

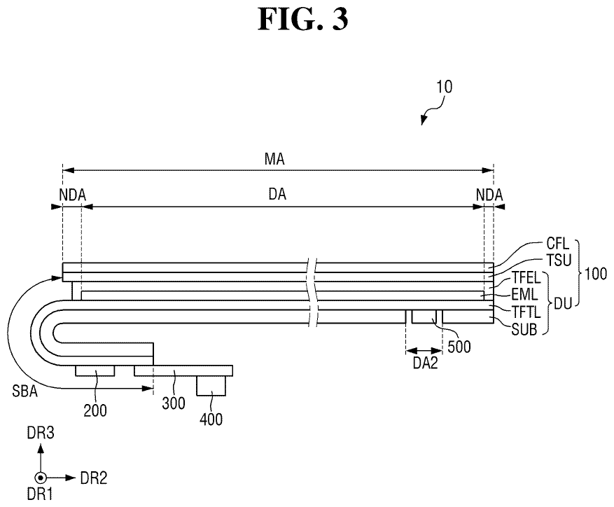

FIG. 3 is a cross-sectional view of the display device of FIG. 2 viewed from the side, according to an embodiment.

In an embodiment and referring to FIG. 3, the display panel 100 may include a display layer DU, a touch sensing layer TSU, and a color filter layer CFL. The display layer DU may include a substrate SUB, a thin film transistor layer TFTL, a light emitting element layer EML, and a thin film encapsulation layer TFEL.

In an embodiment, the substrate SUB may be a base substrate or a base member. The substrate SUB may be a flexible substrate that may be bent, folded, and/or rolled. For example, the substrate SUB may include a polymer resin such as polyimide (PI), but is not limited thereto. In another embodiment, the substrate SUB may include a glass material and/or a metal material.

In an embodiment, the thin film transistor layer TFTL may be disposed on the substrate SUB. The thin film transistor layer TFTL may include a plurality of thin film transistors constituting pixel circuits of pixels. The thin film transistor layer TFTL may further include gate lines, data lines, power lines, gate control lines, fan-out lines connecting the display driver 200 and the data lines to each other, and lead lines connecting the display driver 200 and the pad parts to each other. Each of the thin film transistors may include a semiconductor region, a source electrode, a drain electrode, and a gate electrode. For example, when the gate driver is formed on one side of the non-display area NDA of the display panel 100, the gate driver may include thin film transistors.

In an embodiment, the thin film transistor layer TFTL may be disposed in the display area DA, the non-display area NDA, and the sub-area SBA. The thin film transistors of each of the pixels, the gate lines, the data lines, and the power lines of the thin film transistor layer TFTL may be disposed in the display area DA. The gate control lines and the fan-out lines of the thin film transistor layer TFTL may be disposed in the non-display area NDA. The lead lines of the thin film transistor layer TFTL may be disposed in the sub-area SBA.

In an embodiment, the light emitting element layer EML may be disposed on the thin film transistor layer TFTL. The light emitting element layer EML may include a plurality of light emitting elements each including a first electrode, a second electrode, and a light emitting layer to emit light and a pixel defining film defining the pixels. The plurality of light emitting elements of the light emitting element layer EML may be disposed in the display area DA.

In an embodiment, the light emitting layer may be an organic light emitting layer including an organic material. The light emitting layer may include a hole transporting layer, an organic light emitting layer, and an electron transporting layer. When the first electrode receives a voltage through the thin film transistor of the thin film transistor layer TFTL and the second electrode receives a cathode voltage, holes and electrons may move to the organic light emitting layer through the hole transporting layer and the electron transporting layer, respectively, and may be combined with each other in the organic light emitting layer to emit light.

In another embodiment, the light emitting element may include a quantum dot light emitting diode including a quantum dot light emitting layer, an inorganic light emitting diode including an inorganic semiconductor, and/or a micro light emitting diode.

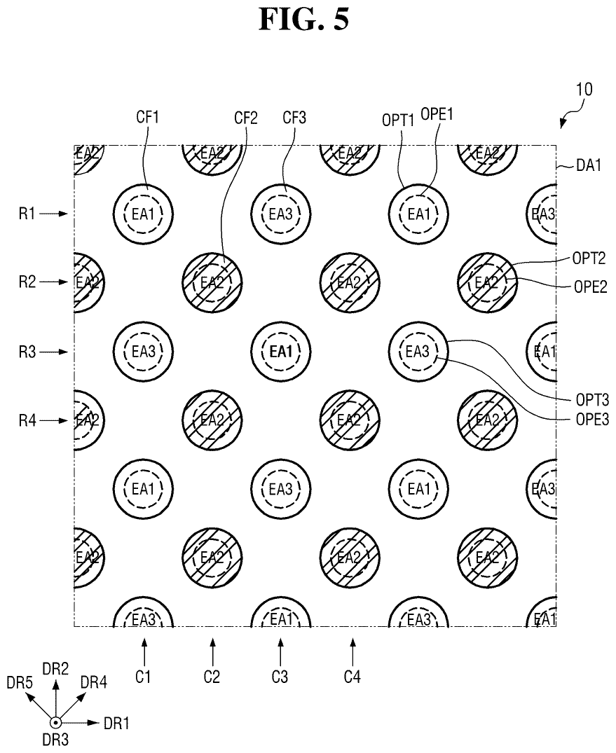

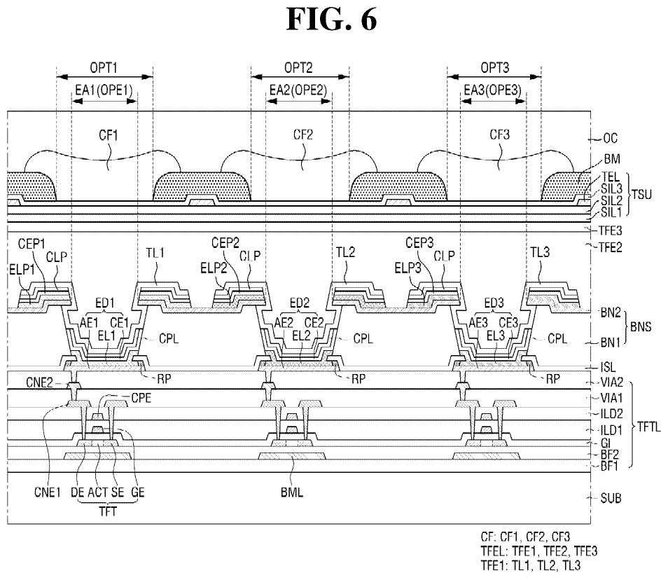

The display device 10 according to an embodiment may include a plurality of color filters CF1, CF2, and CF3 (see FIGS. 5 and 6) disposed on the light emitting elements of the light emitting element layer EML. Each of the color filters may selectively transmit light of a specific wavelength therethrough and block and/or absorb light of other wavelengths. The color filters may absorb some of light introduced from the outside of the display device to reduce reflected light by external light. Accordingly, the color filters may prevent distortion of colors due to external light reflection. Since the color filters are disposed on the light emitting elements, the display device 10 may not require a separate substrate for the color filters. Accordingly, a thickness of the display device 10 may be relatively small.

In an embodiment, the thin film encapsulation layer TFEL may cover an upper surface and side surfaces of the light emitting element layer EML, and may protect the light emitting element layer EML. The thin film encapsulation layer TFEL may include at least one inorganic film and at least one organic film for encapsulating the light emitting element layer EML.

In an embodiment, the touch sensing layer TSU may be disposed on the thin film encapsulation layer TFEL. The touch sensing layer TSU may include a plurality of touch electrodes for sensing a user's touch in a capacitance manner and touch lines connecting the plurality of touch electrodes and the touch driver 400 to each other. For example, the touch sensing layer TSU may sense the user's touch using a mutual capacitance manner or a self-capacitance manner.

In another embodiment, the touch sensing layer TSU may be disposed on a separate substrate disposed on the display layer DU. In this case, the substrate supporting the touch sensing layer TSU may be a base member encapsulating the display layer DU.

In an embodiment, the plurality of touch electrodes of the touch sensing layer TSU may be disposed in a touch sensor area overlapping the display area DA. The touch lines of the touch sensing layer TSU may be disposed in a touch peripheral area overlapping the non-display area NDA.

In some embodiments, the display device 10 may further include an optical device 500. The optical device 500 may be disposed in the second display area DA2. The optical device 500 may emit and/or receive light of infrared, ultraviolet, and/or visible light bands. For example, the optical device 500 may be an optical sensor sensing light incident on the display device 10, such as a proximity sensor, an illuminance sensor, and a camera sensor or an image sensor.

In an embodiment, the color filter layer CFL may be disposed on the thin film encapsulation layer TFEL. The color filter layer CFL may include a plurality of color filters each corresponding to the plurality of emission areas. Each of the color filters may selectively transmit light of a specific wavelength therethrough and block and/or absorb light of other wavelengths. The color filter layer CFL may absorb some of light introduced from the outside of the display device 10 to reduce reflected light by external light. Accordingly, the color filter layer CFL may prevent distortion of colors due to external light reflection.

In an embodiment, since the color filter layer CFL is directly disposed on the thin film encapsulation layer TFEL, the display device 10 may not require a separate substrate for the color filter layer CFL. Accordingly, a thickness of the display device 10 may be relatively small.

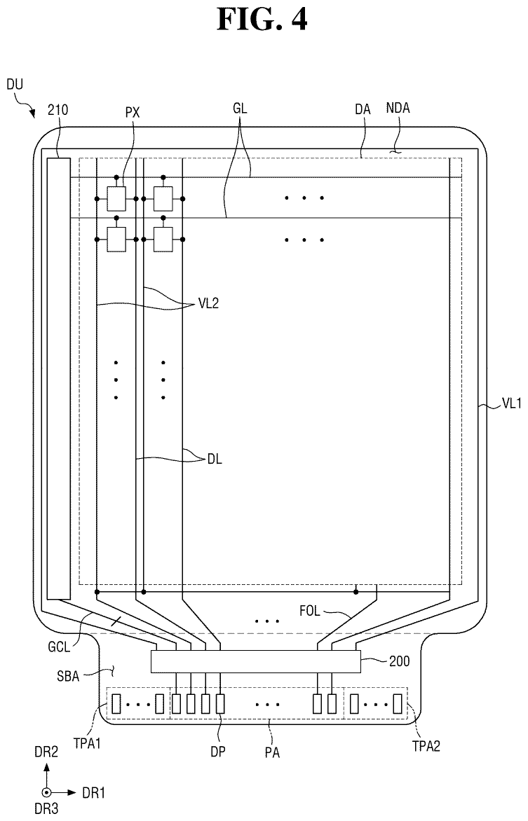

FIG. 4 is a plan view illustrating a display layer of the display device 10, according to an embodiment.

In an embodiment and referring to FIG. 4, the display layer DU may include a display area DA and a non-display area NDA.

In an embodiment, the display area DA may be disposed at the center of the display panel 100 (see FIG. 2). A plurality of pixels PX, a plurality of gate lines GL, a plurality of data lines DL, and some (e.g., second power lines VL2) of a plurality of power lines may be disposed in the display area DA. Each of the plurality of pixels PX may be defined as a minimum unit emitting light.

In an embodiment, the plurality of gate lines GL may supply gate signals received from a gate driver 210 to the plurality of pixels PX. The plurality of gate lines GL may extend in the first direction DR1, and may be spaced apart from each other in the second direction DR2 crossing the first direction DR1.

In an embodiment, the plurality of data lines DL may supply data voltages received from the display driver 200 to the plurality of pixels PX. The plurality of data lines DL may extend in the second direction DR2, and may be spaced apart from each other in the first direction DR1.

In an embodiment, the second power lines VL2 of the plurality of power lines may supply a source voltage received from the display driver 200 to the plurality of pixels PX. Here, the source voltage may be at least one of a driving voltage, an initialization voltage, and a reference voltage. A plurality of second power lines VL2 may extend in the second direction DR2, and may be spaced apart from each other in the first direction DR1.

In an embodiment, the non-display areas NDA may surround the display area DA. Some (e.g., a first power line VL1) of the plurality of power lines, the gate driver 210, fan-out lines FOL, and gate control lines GCL may be disposed in the non-display area NDA. The gate driver 210 may generate a plurality of gate signals based on gate control signals, and may sequentially supply the plurality of gate signals to the plurality of gate lines GL according to a set order.

In an embodiment, the fan-out lines FOL may extend from the display driver 200 to the display area DA. The fan-out lines FOL may supply the data voltages received from the display driver 200 to the plurality of data lines DL.

In an embodiment, the gate control lines GCL may extend from the display driver 200 to the gate driver 210. The gate control lines GCL may supply the gate control signals received from the display driver 200 to the gate driver 210. It has been illustrated in FIG. 4 that the gate driver 210 is disposed only in a non-display area NDA and disposed on the left side of the display area DA, but the invention is not limited thereto. In some embodiments, the display device 10 may include a plurality of gate drivers 210 disposed respectively on the left side and/or the right side of the display area DA.

In an embodiment, the first power line VL1 of the plurality of power lines may be disposed in the non-display area NDA while surrounding the display area DA. The first power line VL1 may supply a source voltage received from the display driver 200 to the plurality of pixels PX. Here, the source voltage may be a low potential source voltage. The first power line VL1 may be electrically connected to the display driver 200 in the non-display area NDA disposed on the lower side of the display area DA, and may be disposed to surround the display area DA by including portions extending in the first direction DR1 and the second direction DR2. The first power line VL1 may be electrically connected to a bank structure BNS (see FIG. 6) to be described later at left and right outer portions of the display layer DU. The first power line VL1 may be electrically connected to the plurality of pixels PX of the display area DA through the bank structure BNS.

In an embodiment, the sub-area SBA may include the display driver 200, a pad area PA, and first and second touch pad areas TPA1 and TPA2, respectively.

In an embodiment, the display driver 200 may output signals and voltages for driving the display panel 100 to the fan-out lines FOL. The display driver 200 may supply the data voltages to the data lines DL through the fan-out lines FOL. The data voltages may be supplied to the plurality of pixels PX, and may control luminance of the plurality of pixels PX. The display driver 200 may supply the gate control signals to the gate driver 210 through the gate control lines GCL.

In an embodiment, the pad area PA, the first touch pad area TPA1, and the second touch pad area TPA2 may be disposed at an edge of the sub-area SBA. The pad area PA, the first touch pad area TPA1, and the second touch pad area TPA2 may be electrically connected to the circuit board 300 using a material such as an anisotropic conductive film or a self-assembly anisotropic conductive paste (SAP).

In an embodiment, the pad area PA may include a plurality of display pad parts DP. The plurality of display pad parts DP may be connected to a graphic system through the circuit board 300. The plurality of display pad parts DP may be connected to the circuit board 300 to receive digital video data, and may supply the digital video data to the display driver 200.

FIG. 5 is a plan view illustrating arrangements of emission areas and color filters in a display area of the display device 10, according to an embodiment.

In an embodiment and referring to FIG. 5, the display device 10 may include a plurality of emission areas EA1, EA2, and EA3 disposed in the display area DA. The display area DA illustrated in FIG. 5 is the first display area DA1, and the plurality of emission areas EA1, EA2, and EA3 may be disposed in the first display area DA1.

In an embodiment, the emission areas EA1, EA2, and EA3 may include first emission areas EA1, second emission areas EA2, and third emission areas EA3 that emit light of different colors. The first to third emission areas EA1, EA2, and EA3, respectively, may emit red, green, or blue light, respectively, and colors of the light emitted from the respective emission areas EA1, EA2, and EA3 may be different depending on the types of light emitting element ED1, ED2, and ED3 (see FIG. 6) are disposed at a light emitting element layer EML to be described later. In an embodiment, the first emission area EA1 may emit first light, which is the red light, the second emission area EA2 may emit second light, which is the green light, and the third emission area EA3 may emit third light, which is the blue light. However, the invention is not limited thereto.

In an embodiment, the plurality of emission areas EA1, EA2, and EA3 may be disposed in a PenTile™ type, for example, a diamond PenTile™ type. For example, the first emission areas EA1 and the third emission areas EA3 may be disposed to be spaced apart from each other in the first direction DR1, and may be alternately disposed in the first direction DR1 and the second direction DR2. In an arrangement of the emission areas EA1, EA2, and EA3, the first emission areas EA1 and the third emission areas EA3 may be alternately disposed in the first direction DR1 in a first row R1 and a third row R3. The first emission areas EA1 and the third emission areas EA3 may be alternately disposed in the second direction DR2 in a first column C1 and a third column C3.

In an embodiment, the second emission areas EA2 may be spaced apart from other adjacent second emission areas EA2 in the first direction DR1 and the second direction DR2, and may be spaced apart from adjacent first emission areas EA1 and third emission areas EA3 in a fourth direction DR4 or a fifth direction DR5. A plurality of second emission areas EA2 may be repeatedly disposed along the first direction DR1 and the second direction DR2, and the second emission areas EA2 and the first emission areas EA1 or the second emission areas EA2 and the third emission areas EA3 may be alternately disposed along the fourth direction DR4 or the fifth direction DR5. In the arrangement of the emission areas EA1, EA2, and EA3, the second emission areas EA2 may be repeatedly disposed in the first direction DR1 in a second row R2 and a fourth row R4, and the second emission areas EA2 may be repeatedly disposed in the second direction DR2 in a second column C2 and a fourth column C4.

In an embodiment, the first to third emission areas EA1, EA2, and EA3, respectively, may be defined, respectively, by a plurality of openings OPE1, OPE2, and OPE3 formed in a bank structure BNS (see FIG. 6) of a light emitting element layer EML to be described later. For example, the first emission area EA1 may be defined by a first opening OPE1 of the pixel defining film, the second emission area EA2 may be defined by a second opening OPE2 of the pixel defining film, and the third emission area EA3 may be defined by a third opening OPE3 of the pixel defining film.

In an embodiment, areas of the emission areas EA1, EA2, and EA3 may change depending on sizes of the openings OPE1, OPE2, and OPE3 of the bank structure. Intensities of the light emitted from the emission areas EA1, EA2, and EA3 may change depending on the areas of the emission areas EA1, EA2, and EA3, and a color feeling of a screen displayed on the display device 10 or the electronic device 1 may be controlled by adjusting the areas of the emission area EA1, EA2, and EA3. In an embodiment, areas or sizes of the first to third emission areas EA1, EA2, and EA3, respectively, may be the same as each other. In an embodiment of FIG. 5, areas or diameters of the first emission area EA1, the second emission area EA2, and the third emission area EA3 may be the same as each other.

However, the invention is not limited thereto. In an embodiment, the areas of the emission areas EA1, EA2, and EA3 may be freely adjusted according to a color feeling of the screen required by the display device 10 and the electronic device 1. In addition, the areas of the emission areas EA1, EA2, and EA3 may be related to light efficiency, lifespan of light emitting elements ED, and the like, and may have a trade-off relationship with external light reflection. The areas of the emission areas EA1, EA2, and EA3 may be adjusted in consideration of the above factors. For example, in the display device 10, an area of the third emission area EA3 may be greater than areas of the first emission area EA1 and the second emission area EA2, and an area of the first emission area EA1 may be greater than an area of the second emission area EA2.

In an embodiment, in the display device 10 having the arrangement of the emission areas EA1, EA2, and EA3 as illustrated in FIG. 5, one first emission area EA1, two second emission areas EA2, and one third emission area EA3 disposed adjacent to each other may form one pixel group. One pixel group may include the emission areas EA1, EA2, and EA3 emitting light of different colors to express a white gradation. However, the invention is not limited thereto, and a combination of the emission areas EA1, EA2, and EA3 constituting one pixel group may be variously modified depending on an arrangement of the emission areas EA1, EA2, and EA3, colors of the light emitted by the emission areas EA1, EA2, and EA3, and the like.

In an embodiment, the display device 10 may include a plurality of color filters CF1, CF2, and CF3 disposed on the emission areas EA1, EA2, and EA3. The plurality of color filters CF1, CF2, and CF3 may be disposed to correspond to the emission areas EA1, EA2, and EA3, respectively. For example, the color filters CF1, CF2, and CF3 may be disposed in a plurality of opening holes OPT1, OPT2, and OPT3 of a light blocking layer BM (see FIG. 6) disposed to correspond to the emission areas EA1, EA2, and EA3 or the openings OPE1, OPE2, and OPE3, respectively. The opening holes OPT1, OPT2, and OPT3 of the light blocking layer may be formed to overlap the openings OPE1, OPE2, and OPE3, respectively, and may form light emitting areas through which the light emitted from the emission areas EA1, EA2, and EA3 is emitted. Each of the color filters CF1, CF2, and CF3 may have a greater area than each of the openings OPE1, OPE2, and OPE3, and may completely cover each of the light emitting areas formed by the opening holes OPT1, OPT2, and OPT3 of the light blocking layer BM.

In an embodiment, the color filters CF1, CF2, and CF3 may include first color filters CF1, second color filters CF2, and third color filters CF3 disposed to correspond to different emission areas EA1, EA2, and EA3, respectively. The color filters CF1, CF2, and CF3 may include colorants, such as dyes or pigments, absorbing light of wavelength bands other than light of a specific wavelength band, and may be disposed to correspond to the colors of the light emitting from the emission areas EA1, EA2, and EA3. For example, the first color filter CF1 may be a red color filter disposed to overlap the first emission area EA1 and transmitting only the first light, which is the red light, therethrough. The second color filter CF2 may be a green color filter disposed to overlap the second emission area EA2 and transmitting only the second light, which is the green light, therethrough, and the third color filter CF3 may be a blue color filter disposed to overlap the third emission area EA3 and transmitting only the third light, which is the blue light, therethrough.

In an embodiment, similar to the arrangement of the emission areas EA1, EA2, and EA3, the color filters CF1, CF2, and CF3 may be disposed in a PenTile™ type, for example, a diamond PenTile™ type. For example, the first color filters CF1 and the third color filters CF3 may be alternately disposed in the first direction DR1 and the second direction DR2. In an arrangement of the color filters CF1, CF2, and CF3, the first color filters CF1 and the third color filters CF3 may be alternately disposed in the first direction DR1 in the first row R1 and the third row R3. The first color filters CF1 and the third color filters CF3 may be alternately disposed in the second direction DR2 in the first column C1 and the third column C3.

In an embodiment, the second color filters CF2 may be spaced apart from other adjacent second color filters CF2 in the first direction DR1 and the second direction DR2, and may be spaced apart from adjacent first color filters CF1 and third color filters CF3 in the fourth direction DR4 or the fifth direction DR5. A plurality of second color filters CF2 may be repeatedly disposed along the first direction DR1 and the second direction DR2, and the second color filters CF2 and the first color filters CF1 or the second color filters CF2 and the third color filters CF3 may be alternately disposed along the fourth direction DR4 or the fifth direction DR5. In the arrangement of the color filters CF1, CF2, and CF3, the second color filters CF2 may be repeatedly disposed in the first direction DR1 in the second row R2 and the fourth row R4, and the second color filters CF2 may be repeatedly disposed in the second direction DR2 in the second column C2 and the fourth column C4.

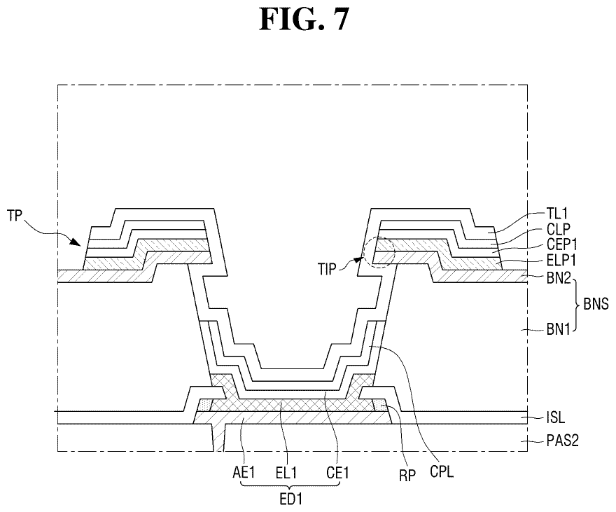

FIG. 6 is a cross-sectional view illustrating a portion of the display device 10, according to an embodiment. FIG. 7 is an enlarged view illustrating a first emission area of FIG. 6, according to an embodiment. In an embodiment, FIG. 6 is a partial cross-sectional view of the display device 10, and illustrates cross sections of the substrate SUB, the thin film transistor layer TFTL, the light emitting element layer EML, and the thin film encapsulation layer TFEL of the display layer DU, the touch sensing layer TSU, and the color filter layer CFL. FIG. 7 illustrates a first light emitting element ED1 disposed in a first emission area EA1 and a portion of a bank structure BNS around the first light emitting element ED1 in FIG. 6.

In an embodiment and referring to FIGS. 6 and 7 in addition to FIG. 5, the display panel 100 of the display device 10 (see FIG. 3) may include the display layer DU. The display layer DU may include the substrate SUB, the thin film transistor layer TFTL, the light emitting element layer EML, and the thin film encapsulation layer TFEL. The display panel 100 may include a light blocking layer BM disposed on the thin film encapsulation layer TFEL, and color filters CF1, CF2, and CF3 of the color filter layer CFL may be disposed on the light blocking layer BM.

In an embodiment, the substrate SUB may be a base substrate or a base member. The substrate SUB may be a flexible substrate that may be bent, folded, and/or rolled. As an example, the substrate SUB may include a polymer resin such as polyimide (PI), but is not limited thereto. As another example, the substrate SUB may include a glass material or a metal material.

In an embodiment, the thin film transistor layer TFTL may include a first buffer layer BF1, a lower metal layer BML, a second buffer layer BF2, first thin film transistors TFT1, a gate insulating layer GI, a first interlayer insulating layer ILD1, capacitor electrodes CPE, a second interlayer insulating layer ILD2, first connection electrodes CNE1, a first via layer VIA1, second connection electrodes CNE2, and a second via layer VIA2.

In an embodiment, the first buffer layer BF1 may be disposed on the substrate SUB. The first buffer layer BF1 may include an inorganic film capable of preventing permeation of air or moisture. For example, the first buffer layer BF1 may include a plurality of inorganic films that are alternately stacked.

In an embodiment, the lower metal layer BML may be disposed on the first buffer layer BF1. For example, the lower metal layer BML may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

In an embodiment, the second buffer layer BF2 may cover the first buffer layer BF1 and the lower metal layer BML. The second buffer layer BF2 may include an inorganic film capable of preventing permeation of air or moisture. For example, the second buffer layer BF2 may include a plurality of inorganic films that are alternately stacked.

In an embodiment, the first thin film transistor TFT1 may be disposed on the second buffer layer BF2, and may constitute a pixel circuit of each of the plurality of pixels. For example, the first thin film transistor TFT1 may be a driving transistor or a switching transistor of the pixel circuit disposed in the display area DA. The first thin film transistor TFT1 may include a semiconductor layer ACT, a source electrode SE, a drain electrode DE, and a gate electrode GE.

In an embodiment, the semiconductor layer ACT may be disposed on the second buffer layer BF2. The semiconductor layer ACT may overlap the lower metal layer BML and the gate electrode GE in the thickness direction, and may be insulated from the gate electrode GE by the gate insulating layer GI. A material of the semiconductor layer ACT in portions of the semiconductor layer ACT may become conductors to form the source electrode SE and the drain electrode DE.

In an embodiment, the gate electrode GE may be disposed on the gate insulating layer GI. The gate electrode GE may overlap the semiconductor layer ACT with the gate insulating layer GI interposed therebetween.

In an embodiment, the gate insulating layer GI may be disposed on the semiconductor layer ACT. For example, the gate insulating layer GI may cover the semiconductor layer ACT and the second buffer layer BF2, and may insulate the semiconductor layer ACT and the gate electrode GE from each other. The gate insulating layer GI may include contact holes through which the first connection electrodes CNE1 penetrate.

In an embodiment, the first interlayer insulating layer ILD1 may cover the gate electrode GE and the gate insulating layer GI. The first interlayer insulating layer ILD1 may include contact holes through which the first connection electrodes CNE1 penetrate. The contact holes of the first interlayer insulating layer ILD1 may be connected to the contact holes of the gate insulating layer GI and contact holes of the second interlayer insulating layer ILD2.

In an embodiment, the capacitor electrodes CPE may be disposed on the first interlayer insulating layer ILD1. The capacitor electrode CPE may overlap the gate electrode GE in the thickness direction. The capacitor electrode CPE and the gate electrode GE may form a capacitance.

In an embodiment, the second interlayer insulating layer ILD2 may cover the capacitor electrodes CPE and the first interlayer insulating layer ILD1. The second interlayer insulating layer ILD2 may include contact holes through which the first connection electrodes CNE1 penetrate. The contact holes of the second interlayer insulating layer ILD2 may be connected to the contact holes of the first interlayer insulating layer ILD1 and the contact holes of the gate insulating layer GI.

In an embodiment, the first connection electrodes CNE1 may be disposed on the second interlayer insulating layer ILD2. The first connection electrodes CNE1 may electrically connect the drain electrodes DE of the first thin film transistors TFT1 and the second connection electrodes CNE2 to each other. The first connection electrodes CNE1 may be inserted into the contact holes formed in the second interlayer insulating layer ILD2, the first interlayer insulating layer ILD1, and the gate insulating layer GI to be in contact with the drain electrodes DE of the first thin film transistors TFT1.

In an embodiment, the first via layer VIA1 may cover the first connection electrodes CNE1 and the second interlayer insulating layer ILD2. The first via layer VIA1 may protect the first thin film transistors TFT1. The first via layer VIA1 may include contact holes through which the second connection electrodes CNE2 penetrate.

In an embodiment, the second connection electrodes CNE2 may be disposed on the first via layer VIA1. The second connection electrodes CNE2 may electrically connect the first connection electrodes CNE1 and anode electrodes AE1, AE2, and AE3 of light emitting elements ED to each other. The second connection electrodes CNE2 may be inserted into the contact holes formed in the first via layer VIA1 to be in contact with the first connection electrodes CNE1.

In an embodiment, the second via layer VIA2 may cover the second connection electrodes CNE2 and the first via layer VIA1. The second via layer VIA2 may include contact holes through which the anode electrodes AE1, AE2, and AE3 of the light emitting elements ED penetrate.

In an embodiment, the light emitting element layer EML may be disposed on the thin film transistor layer TFTL. The light emitting element layer EML may include the light emitting elements ED and a plurality of bank structures BNS. The light emitting elements ED may include the anode electrodes AE1, AE2, and AE3, light emitting layers EL1, EL2, and EL3, and cathode electrodes CE1, CE2, and CE3.

In an embodiment, the display device 10 may include a plurality of emission areas EA1, EA2, and EA3 disposed in the display area DA. The emission areas EA1, EA2, and EA3 may include a first emission area EA1, a second emission area EA2, and a third emission area EA3 that emit light of different colors. The first to third emission areas EA1, EA2, and EA3, respectively, may emit red, green, or blue light, respectively, and colors of the light emitted from the emission areas EA1, EA2, and EA3 may be different depending on the types of the light emitting elements ED disposed in the light emitting element layer EML. In an embodiment, the first emission area EA1 may emit a first light, which is the red light, the second emission area EA2 may emit a second light, which is the green light, and the third emission area EA3 may emit a third light, which is the blue light. However, the invention is not limited thereto.

In an embodiment, the first to third emission areas EA1, EA2, and EA3, respectively, may be defined, respectively, by a plurality of openings OPE1, OPE2, and OPE3 formed in the bank structure BNS of the light emitting element layer EML. For example, the first emission area EA1 may be defined by a first opening OPEL of the bank structure BNS, the second emission area EA2 may be defined by a second opening OPE2 of the bank structure BNS, and the third emission area EA3 may be defined by a third opening OPE3 of the bank structure BNS.

In an embodiment, areas or sizes of the first to third emission areas EA1, EA2, and EA3, respectively, may be the same as each other. For example, in the display device 10, the openings OPE1, OPE2, and OPE3 of the bank structures BNS may have the same diameter, and the first emission area EA1, the second emission area EA2, and the third emission area EA3 may have the same area. However, the invention is not limited thereto. In the display device 10, areas or sizes of the first to third emission areas EA1, EA2, and EA3, respectively, may be different from each other. For example, an area of the second emission area EA2 may be greater than areas of the first emission area EA1 and the third emission area EA3, and an area of the third emission area EA3 may be greater than an area of the first emission area EA1. Intensities of the light emitted from the emission areas EA1, EA2, and EA3 may change depending on the areas of the emission areas EA1, EA2, and EA3, and a color feeling of a screen displayed on the display device 10 or the electronic device 1 may be controlled by adjusting the areas of the emission area EA1, EA2, and EA3. In an embodiment of FIG. 5, it has been illustrated that the areas of the emission areas EA1, EA2, and EA3 are the same as each other, but the invention is not limited thereto. The areas of the emission areas EA1, EA2, and EA3 may be freely adjusted according to a color feeling of the screen required by the display device 10 and the electronic device 1. In addition, the areas of the emission areas EA1, EA2, and EA3 may be related to light efficiency, lifespan of light emitting elements ED, and the like, and may have a trade-off relationship with external light reflection. The areas of the emission areas EA1, EA2, and EA3 may be adjusted in consideration of the above factors.

In an embodiment, in the display device 10, one first emission area EA1, one second emission area EA2, and one third emission area EA3 disposed adjacent to each other may form one pixel group. One pixel group may include the emission areas EA1, EA2, and EA3 emitting light of different colors to express a white gradation. However, the disclosure is not limited thereto, and a combination of the emission areas EA1, EA2, and EA3 constituting one pixel group may be variously modified depending on an arrangement of the emission areas EA1, EA2, and EA3, colors of the light emitted by the emission areas EA1, EA2, and EA3, and/or the like.

In an embodiment, the display device 10 may include a plurality of light emitting elements ED1, ED2, and ED3 disposed in different emission areas EA1, EA2, and EA3. The light emitting elements ED1, ED2, and ED3 may respectively include a first light emitting element ED1 disposed in the first emission area EA1, a second light emitting element ED2 disposed in the second emission area EA2, and a third light emitting element ED3 disposed in the third emission area EA3. The light emitting elements ED1, ED2, and ED3 may include anode electrodes AE1, AE2, and AE3, light emitting layers EL1, EL2, and EL3, and cathode electrodes CE1, CE2, and CE3, respectively, and the light emitting elements ED1, ED2, and ED3 disposed in the different emission areas EA1, EA2, and EA3, respectively, may emit light of different colors depending on materials of the light emitting layers EL1, EL2, and EL3, respectively. For example, the first light emitting element ED1 disposed in the first emission area EA1 may emit red light, which is light of a first color, the second light emitting element ED2 disposed in the second emission area EA2 may emit green light, which is light of a second color, and the third light emitting element ED3 disposed in the third emission area EA3 may emit blue light, which is light of a third color. The first to third emission areas EA1, EA2, and EA3, respectively, constituting one pixel may include the light emitting elements ED1, ED2, and ED3, respectively, emitting the light of the different colors to express a white gradation.

In an embodiment, the anode electrodes AE1, AE2, and AE3 may be disposed on the second via layer VIA2. Each of the anode electrodes AE1, AE2, and AE3 may be disposed to overlap any one of the openings OPE1, OPE2, and OPE3 of the bank structure BNS. The anode electrodes AE1, AE2, and AE3 may be electrically connected to the drain electrodes DE of the first thin film transistors TFT1 through the first and second connection electrodes CNE1 and CNE2.

In an embodiment, the anode electrodes AE1, AE2, and AE3 may be disposed in the plurality of emission areas EA1, EA2, and EA3, respectively. The anode electrodes AE1, AE2, and AE3 may include a first anode electrode AE1 disposed in the first emission area EA1, a second anode electrode AE2 disposed in the second emission area EA2, and a third anode electrode AE3 disposed in the third emission area EA3. The first anode electrode AE1, the second anode electrode AE2, and the third anode electrode AE3 may be disposed to be spaced apart from each other on the second via layer VIA2, respectively. The anode electrodes AE1, AE2, and AE3 may be disposed in the different emission areas EA1, EA2, and EA3, respectively, to constitute the light emitting elements ED1, ED2, and

ED3 emitting the light of the different colors, respectively.

In an embodiment, an inorganic insulating layer ISL may be disposed on the second via layer VIA2 and the anode electrodes AE1, AE2, and AE3. The inorganic insulating layer ISL may be entirely disposed on the second via layer VIA2, but may expose portions of upper surfaces of the anode electrodes AE1, AE2, and AE3 while partially overlapping the anode electrodes AE1, AE2, and AE3. The inorganic insulating layer ISL may expose the anode electrodes AE1, AE2, and AE3 in portions thereof overlapping the openings OPE1, OPE2, and OPE3, respectively, of the bank structure BNS, and the light emitting layers EL1, EL2, and EL3 disposed on the anode electrodes AE1, AE2, and AE3, respectively, may be directly disposed on the anode electrodes AE1, AE2, and AE3, respectively. The inorganic insulating layer ISL may include an inorganic insulating material. As an example, the inorganic insulating layer ISL may include aluminum oxide, titanium oxide, tantalum oxide, hafnium oxide, zinc oxide, silicon oxide, silicon nitride, and/or silicon oxynitride.

According to an embodiment, the inorganic insulating layer ISL may be disposed on the anode electrodes AE1, AE2, and AE3, but may be spaced apart from the upper surfaces of the anode electrodes AE1, AE2, and AE3. The inorganic insulating layer ISL may not be in direct contact with the anode electrodes AE1, AE2, and AE3 while partially overlapping the anode electrodes AE1, AE2, and AE3, and portions of the light emitting layers EL1, EL2, and EL3 of the light emitting elements ED1, ED2, and ED3, respectively, may be disposed between the inorganic insulating layer ISL and the anode electrodes AE1, AE2, and AE3, respectively. In a manufacturing process of the display device 10, a sacrificial layer may be disposed on the anode electrodes AE1, AE2, and AE3 before the inorganic insulating layer ISL is formed. The inorganic insulating layer ISL may be disposed to cover portions of the sacrificial layer, and may then be spaced apart from the upper surfaces of the anode electrodes AE1, AE2, and AE3 while the sacrificial layer is removed. The inorganic insulating layer ISL may have a shape in which it protrudes from residual patterns RP toward inner sides of the openings OPE1, OPE2, and OPE3. Thereafter, in a deposition process of the light emitting layers EL1, EL2, and EL3, portions of the inorganic insulating layer ISL may be disposed on the light emitting layers EL1, EL2, and EL3 while materials forming the light emitting layers EL1, EL2, and EL3 fill spaces between the inorganic insulating layer ISL and the anode electrodes AE1, AE2, and AE3, respectively. However, the inorganic insulating layer ISL may be in direct contact with side surfaces of the anode electrodes AE1, AE2, and AE3.

In an embodiment, the display device 10 may include the plurality of bank structures BNS disposed on the thin film transistor layer TFTL or the substrate SUB and including the plurality of openings OPE1, OPE2, and OPE3. The bank structure BNS may have a structure in which bank layers BN1 and BN2 including different materials are sequentially stacked, and may include the plurality of openings OPE1, OPE2, and OPE3 forming the emission areas EA1, EA2, and EA3, respectively. The light emitting elements ED1, ED2, and ED3 of the display device 10 may be disposed to overlap the openings OPE1, OPE2, and OPE3, respectively, of the bank structure BNS.

In an embodiment, the bank structure BNS may include a first bank layer BN1 disposed on the inorganic insulating layer ISL and a second bank layer BN2 disposed on the first bank layer BN1.

According to an embodiment, the first bank layer BN1 and the second bank layer BN2 may include different metal materials, and the second bank layer BN2 of the bank structure BNS may include tips TIP protruding from the first bank layer BN1 toward the openings OPE1, OPE2, and OPE3. In the bank structure BNS, sides of the first bank layer BN1 may have a shape in which they are recessed inward from sides of the second bank layer BN2. In the bank structure BNS, the first bank layer BN1 may have a greater thickness than the second bank layer BN2, and the second bank layer BN2 may have a relatively small thickness and include the tips TIP formed in a manufacturing process. The second bank layer BN2 has a shape in which it protrudes more than the first bank layer BN1 toward the openings OPE1, OPE2, and OPE3, and accordingly, inner sidewalls of the openings OPE1, OPE2, and OPE3 of the bank structure BNS may have undercuts formed under the tips TIP of the second bank layer BN2.

In an embodiment, a sidewall shape of the bank structure BNS may be a structure formed due to a difference in etch rate between the first bank layer BN1 and the second bank layer BN2 in an etching process because the first bank layer BN1 and the second bank layer BN2 include different materials. According to an embodiment, the second bank layer BN2 may include a material having an etch rate that is slower than that of the first bank layer BN1, and the first bank layer BN1 may be further etched in a process of forming the openings OPE1, OPE2, and OPE3 of the bank structure BNS, such that the undercuts may be formed under the tips TIP of the second bank layer BN2. In an embodiment, the first bank layer BN1 may include a metal material having high electrical conductivity, and the second bank layer BN2 may include a metal material having low reflectivity. As an example, the first bank layer BN1 may include aluminum (Al), and the second bank layer BN2 may include titanium (Ti). The bank structure BNS may have a structure in which an Al layer and a Ti layer are stacked on the inorganic insulating layer ISL, and the tips TIP may be formed in the Ti layer of the second bank layer BN2.

In an embodiment, the bank structure BNS may include the openings OPE1, OPE2, and OPE3 forming the emission areas EA1, EA2, and EA3, respectively, and the light blocking layer BM may be disposed on the bank structure BNS. The uppermost layer of the bank structure BNS may include a material having low reflectivity to reduce external light reflection. In addition, in the bank structure BNS, the first bank layer BN1 may be electrically connected to the cathode electrodes CE1, CE2, and CE3 of different light emitting elements ED1, ED2, and ED3, respectively. The cathode electrodes CE1, CE2, and CE3 of the light emitting elements ED1, ED2, and ED3, respectively, disposed in the different emission areas EA1, EA2, and EA3, respectively, are not directly connected to each other, but may be electrically connected to each other through the first bank layer BN1 of the bank structure BNS.

In an embodiment, in order to form the pixel defining film forming the emission areas EA1, EA2, and EA3 using an organic material or form the light emitting layers EL1, EL2, and EL3 of the light emitting elements ED1, ED2 and ED3, respectively, for each of the emission areas EA1, EA2, and EA3, respectively, in the manufacturing process of the display device 10, a mask process is required. The display device 10 may require a structure for mounting a mask in order to perform the mask process or require an unnecessarily great area of the non-display area NDA in order to control dispersion according to the mask process. When such a mask process is minimized, an unnecessary component such as the structure for mounting the mask may be omitted from the display device 10, and the area of the non-display area NDA for controlling the dispersion may be minimized.

The display device 10 according to an embodiment includes the bank structure BNS forming the emission areas EA1, EA2, and EA3, and thus, the light emitting layers EL1, EL2, and EL3 may be formed by deposition and etching processes instead of the mask process. In addition, the bank structure BNS includes the first bank layer BN1 and the second bank layer BN2 including the different metal materials to have a structure in which the inner sidewalls of the openings OPE1, OPE2, and OPE3 include the tips TIP, and accordingly, it is possible to individually form different layers in the different emission areas EA1, EA2, and EA3 even though the deposition process. For example, even though the light emitting layers EL1, EL2, and EL3 and the cathode electrodes CE1, CE2, and CE3 of the light emitting elements ED1, ED2, and ED3, respectively, are formed by a deposition process that does not use the mask, deposited materials may be disconnected from each other rather than being connected to each other between the openings OPE1, OPE2, and OPE3 by the tips TIP of the second bank layer BN2 formed on the inner sidewalls of the openings OPE1, OPE2, and OPE3. It is possible to form individually the different layers in the different emission areas EA1, EA2, and EA3 through a process of forming a material for forming a specific layer on the entire surface of the display device 10 and then etching and removing a layer formed in unwanted areas. In the display device 10, through the deposition and etching processes without using the mask process, the different light emitting elements ED1, ED2, and ED3 may be formed for each of the emission areas EA1, EA2, and EA3, respectively, the unnecessary component may be omitted from the display device 10, and the area of the non-display area NDA may be minimized.

In an embodiment, a first encapsulation layer TFE1 of the thin film encapsulation layer TFEL may be disposed on the cathode electrodes CE1, CE2, and CE3 of the light emitting elements ED1, ED2, and ED3, respectively. The first encapsulation layer TFE1 may include a first inorganic layer TL1 disposed on the first light emitting element ED1, a second inorganic layer TL2 disposed on the second light emitting element ED2, and a third inorganic layer TL3 disposed on the third light emitting element ED3. After the first to third inorganic layers TL1, TL2, and TL3, respectively, are entirely formed on the bank structure BNS, the first to third inorganic layers TL1, TL2, and TL3, respectively, may be disposed to cover only the light emitting elements ED1, ED2, and ED3, respectively, in the respective emission areas EA1, EA2, and EA3 and organic patterns ELP1, ELP2, and ELP3 and electrode patterns CEP1, CEP2, and CEP3 to be described later, but may not be disposed between the emission areas EA1, EA2, and EA3. The inorganic layers TL1, TL2, and TL3 may be formed in such a shape by forming the inorganic layers TL1, TL2, and TL3 so as to completely cover the bank structure BNS and then partially patterning the inorganic layers TL1, TL2, and TL3.

In an embodiment, the display device 10 may include patterns that are traces according to a shape and a deposition process of the bank structure BNS. These patterns may be formed simultaneously with the light emitting layers EL1, EL2, and EL3 and the cathode electrodes CE1, CE2, and CE3 of the light emitting elements ED1, ED2, and ED3, respectively, and may remain on the bank structure BNS. Hereinafter, structures of the light emitting layers EL1, EL2, and EL3 and the cathode electrodes CE1, CE2, and CE3, and the patterns will be described.

In an embodiment, the light emitting layers EL1, EL2, and EL3 may be disposed on the anode electrodes AE1, AE2, and AE3, respectively. The light emitting layers EL1, EL2, and EL3 may be organic light emitting layers made of an organic material, and may be formed on the anode electrodes AE1, AE2, and AE3, respectively, through a deposition process. When the first thin film transistors TFT1 apply a predetermined voltage to the anode electrodes AE1, AE2, and AE3 of the light emitting elements ED1, ED2, and ED3, respectively, and the cathode electrodes CE1, CE2, and CE3 of the light emitting elements ED1, ED2, and ED3, respectively, receives a common voltage or a cathode voltage, holes and electrons may move to the light emitting layers EL1, EL2, and EL3 through hole transporting layers and electron transporting layers, respectively, and may be combined with each other in the light emitting layers EL1, EL2, and EL3 to emit light.

In an embodiment, the light emitting layers EL1, EL2, and EL3 may include a first light emitting layer EL1, a second light emitting layer EL2, and a third light emitting layer EL3 disposed in the different emission areas EA1, EA2, and EA3, respectively. The first light emitting layer EL1 may be disposed on the first anode electrode AE1 in the first emission area EA1, the second light emitting layer EL2 may be disposed on the second anode electrode AE2 in the second emission area EA2, and the third light emitting layer EL3 may be disposed on the third anode electrode AE3 in the third emission area EA3. The first to third light emitting layers EL1, EL2, and EL3, respectively, may be light emitting layers of the first to third light emitting elements ED1, ED2 and ED3, respectively. The first light emitting layer EL1 may be a light emitting layer emitting the red light, which is the light of the first color, the second light emitting layer EL2 may be a light emitting layer emitting the green light, which is the light of the second color, and the third light emitting layer EL3 may be a light emitting layer emitting the blue light, which is the light of the third color.

According to an embodiment, portions of the light emitting layers EL1, EL2, and EL3 of the light emitting elements ED1, ED2, and ED3, respectively, may be disposed between the anode electrodes AE1, AE2, and AE3, respectively, and the inorganic insulating layer ISL. The inorganic insulating layer ISL may be disposed on the anode electrodes AE1, AE2, and AE3, but may be spaced apart from the upper surfaces of the anode electrodes AE1, AE2, and AE3. The deposition process of the light emitting layers EL1, EL2, and EL3 may be performed so that materials of the light emitting layers are deposited in a direction inclined with respect to an upper surface of the substrate SUB rather than a direction perpendicular to the upper surface of the substrate SUB. Accordingly, the light emitting layers EL1, EL2, and EL3 may be disposed on the upper surfaces of the anode electrodes AE1, AE2, and AE3, respectively, exposed in the openings OPE1, OPE2, and OPE3, respectively, of the bank structure BNS, and may be disposed to fill spaces between the anode electrodes AE1, AE2, and AE3, respectively, and the inorganic insulating layer ISL.

As described above, in an embodiment, in the manufacturing process of the display device 10, the sacrificial layer may be disposed between the inorganic insulating layer ISL and the anode electrodes AE1, AE2, and AE3, and the light emitting layers EL1, EL2, and EL3 may then be disposed in areas in which the sacrificial layer is partially removed. Accordingly, a lower surface of the inorganic insulating layer ISL may be spaced apart from the anode electrodes AE1, AE2, and AE3. However, the sacrificial layer may remain as partial residual patterns RP in areas between the inorganic insulating layer ISL and the anode electrodes AE1, AE2, and AE3. The areas between the inorganic insulating layer ISL and the anode electrodes AE1, AE2, and AE3 may be filled with the partial residual patterns RP and the light emitting layers EL1, EL2, and EL3, respectively.

The display device 10 according to an embodiment may include a plurality of organic patterns ELP1, ELP2, and ELP3 including the same materials as the light emitting layers EL1, EL2, and EL3, respectively, and disposed on the bank structure BNS. Since the light emitting layers EL1, EL2, and EL3 are formed through a process of depositing materials on the entire surface of the display device 10, the materials forming the light emitting layers EL1, EL2, and EL3 may be deposited on the bank structure BNS as well as in the openings OPE1, OPE2, and OPE3, respectively, of the bank structure BNS.

For example, in an embodiment, the display device 10 may include the organic patterns ELP1, ELP2, and ELP3 disposed above the bank structure BNS. The organic patterns ELP1, ELP2, and ELP3 may include a first organic pattern ELP1, a second organic pattern ELP2, and a third organic pattern ELP3 disposed on the second bank layer BN2 of the bank structure BNS.

In an embodiment, the first organic pattern ELP1 may include the same material as the first light emitting layer EL1 of the first light emitting element ED1. The second organic pattern ELP2 may include the same material as the second light emitting layer EL2 of the second light emitting element ED2, and the third organic pattern ELP3 may include the same material as the third light emitting layer EL3 of the third light emitting element ED3. The organic patterns ELP1, ELP2, and ELP3 may be formed in the same processes as the light emitting layers EL1, EL2, and EL3, respectively, including the same materials as the organic patterns ELP1, ELP2, and ELP3, respectively.

In an embodiment, the first organic pattern ELP1, the second organic pattern ELP2, and the third organic pattern ELP3 may be directly disposed on the second bank layer BN2 of the bank structure BNS. The organic patterns ELP1, ELP2, and ELP3 may be formed in the same processes as the light emitting layers EL1, EL2, and EL3, respectively, including the same materials as the organic patterns ELP1, ELP2, and ELP3, respectively, and may be disposed adjacent to the emission areas EA1, EA2, and EA3, respectively, in which the respective light emitting layers EL1, EL2, and EL3 are disposed. For example, the first organic pattern ELP1 may be disposed on the second bank layer BN2 while surrounding the first opening OPE1 around the first emission area EA1 or the first opening OPE1. The second organic pattern ELP2 may be disposed on the second bank layer BN2 while surrounding the second opening OPE2 around the second emission area EA2 or the second opening OPE2, and the third organic pattern ELP3 may be disposed on the second bank layer BN2 while surrounding the third opening OPE3 around the third emission area EA3 or the third opening OPE3.

In an embodiment, such organic patterns ELP1, ELP2, and ELP3 may be traces formed while the deposited materials are disconnected from the light emitting layers EL1, EL2, and EL3, respectively, rather than being connected to the light emitting layers EL1, EL2, and EL3 because the bank structure BNS includes the tips TIP. The light emitting layers EL1, EL2, and EL3 may be formed in the openings OPE1, OPE2, and OPE3, respectively, and the organic patterns ELP1, ELP2, and ELP3 and the light emitting layers EL1, EL2, and EL3 may be disconnected from each other by the tips TIP formed on the sidewalls of the openings OPE1, OPE2, and OPE3, respectively. The light emitting layers EL1, EL2, and EL3 are formed through the deposition process that does not use the mask, and accordingly, materials of the light emitting layers EL1, EL2, and EL3 may be entirely formed on the bank structure BNS, and the organic patterns ELP1, ELP2, and ELP3 may be formed by patterning these materials around the emission areas EA1, EA2, and EA3 or the openings OPE1, OPE2, and OPE3, respectively.

In an embodiment, the cathode electrodes CE1, CE2, and CE3 may be disposed on the light emitting layers EL1, EL2, and EL3, respectively. The cathode electrodes CE1, CE2, and CE3 may include a transparent conductive material to emit light generated from the light emitting layers EL1, EL2, and EL3, respectively. The cathode electrodes CE1, CE2, and CE3 may receive a common voltage or a low potential voltage. When the anode electrodes AE1, AE2, and AE3 receive a voltage corresponding to a data voltage and the cathode electrodes CE1, CE2, and CE3 receive the low potential voltage, potential differences are formed between the anode electrodes AE1, AE2, and AE3 and the cathode electrodes CE1, CE2, and CE3, respectively, such that the light emitting layers EL1, EL2, and EL3, respectively, may emit light.

In an embodiment, the cathode electrodes CE1, CE2, and CE3 may include a first cathode electrode CE1, a second cathode electrode CE2, and a third cathode electrode CE3, respectively, disposed in the different emission areas EA1, EA2, and EA3, respectively. The first cathode electrode CE1 may be disposed on the first light emitting layer EL1 in the first emission area EA1, the second cathode electrode CE2 may be disposed on the second light emitting layer EL2 in the second emission area EA2, and the third cathode electrode CE3 may be disposed on the third light emitting layer EL3 in the third emission area EA3.

According to an embodiment, portions of the cathode electrodes CE1, CE2, and CE3 of the light emitting elements ED1, ED2, and ED3, respectively, may be disposed on side surfaces of the first bank layer BN1 of the bank structure BNS. Similar to the light emitting layers EL1, EL2, and EL3, the cathode electrodes CE1, CE2, and CE3 may also be formed through a deposition process. The deposition process of the cathode electrodes CE1, CE2, and CE3 may be performed so that electrode materials are deposited in a direction inclined with respect to the upper surface of the substrate SUB rather than the direction perpendicular to the upper surface of the substrate SUB. Accordingly, the cathode electrodes CE1, CE2, and CE3 may be disposed on the side surfaces of the first bank layer BN1 under the tips TIP of the second bank layer BN2 of the bank structure BNS. The cathode electrodes CE1, CE2, and CE3 may be in direct contact with the side surfaces of the first bank layer BN1. The cathode electrodes CE1, CE2, and CE3 of the different light emitting elements ED1, ED2, and ED3, respectively, may be in direct contact with the first bank layer BN1 of the bank structure BNS, respectively, and the cathode electrodes CE1, CE2, and CE3 may be electrically connected to each other. Unlike the anode electrodes AE1, AE2, and AE3, the cathode electrodes CE1, CE2, and CE3 are not divided for each of the plurality of pixels, and may be implemented in an electrode form that is electrically common to all pixels.

According to an embodiment, contact areas between the cathode electrodes CE1, CE2, and CE3 and the side surfaces of the first bank layer BN1 may be greater than contact areas between the light emitting layers EL1, EL2, and EL3 and the side surfaces of the first bank layer BN1. Each of the deposition processes of the cathode electrodes CE1, CE2, and CE3 and the light emitting layers EL1, EL2, and EL3 may be performed so that the materials of the cathode electrodes CE1, CE2, and CE3 and the light emitting layers EL1, EL2, and EL3 are deposited in the direction inclined with respect to the upper surface of the substrate SUB rather than the direction perpendicular to the upper surface of the substrate SUB, and areas of the cathode electrodes CE1, CE2, and CE3 and the light emitting layers EL1, EL2, and EL3 disposed on the side surfaces of the first bank layer BN1 may change depending on an inclined angle. In an embodiment, the deposition process of the cathode electrodes CE1, CE2, and CE3 may be performed in a more inclined direction than the deposition process of the light emitting layers EL1, EL2, and EL3. The cathode electrodes CE1, CE2, and CE3 may be disposed to have a greater area than the light emitting layers EL1, EL2, and EL3, respectively, on the sidewalls of the openings OPE1, OPE2, and OPE3, respectively, or may be disposed up to a greater height on the sidewalls of the openings OPE1, OPE2, and OPE3 than the light emitting layers EL1, EL2, and EL3, respectively. Since the cathode electrodes CE1, CE2, and CE3 of the different light emitting elements ED1, ED2, and ED3, respectively, are electrically connected to each other through the first bank layer BN1, it may be advantageous that the cathode electrodes CE1, CE2, and CE3 are in contact with the first bank layer BN1 in a greater area.

The display device 10 according to an embodiment may include a plurality of electrode patterns CEP1, CEP2, and CEP3 including the same materials as the cathode electrodes CE1, CE2, and CE3 and disposed on the bank structure BNS. Since the cathode electrodes CE1, CE2, and CE3 are formed through a process of depositing materials on the entire surface of the display device 10, materials forming the cathode electrodes CE1, CE2, and CE3 may be deposited on the bank structure BNS as well as in the openings OPE1, OPE2, and OPE3, respectively, of the bank structure BNS.

In an embodiment, the display device 10 may include electrode patterns CEP1,

CEP2, and CEP3 disposed above the bank structure BNS. The electrode patterns CEP1, CEP2, and CEP3 may include a first electrode pattern CEP1, a second electrode pattern CEP2, and a third electrode pattern CEP3, respectively, disposed on the second bank layer BN2 of the bank structure BNS.

For example, in an embodiment, the first electrode pattern CEP1, the second electrode pattern CEP2, and the third electrode pattern CEP3 may be directly disposed on the first organic pattern ELP1, the second organic pattern ELP2, and the third organic pattern ELP3, respectively. An arrangement relationship between the electrode patterns CEP1, CEP2, and CEP3 and the organic patterns ELP1, ELP2, and ELP3, respectively, may be the same as an arrangement relationship between the light emitting layers EL1, EL2, and EL3 and the cathode electrodes CE1, CE2, and CE3, respectively, of the light emitting elements ED1, ED2, and ED3. Such electrode patterns CEP1, CEP2, and CEP3 may be traces formed while the deposited materials are disconnected from the cathode electrodes CE1, CE2, and CE3 rather than being connected to the cathode electrodes CE1, CE2, and CE3 because the bank structure BNS includes the tips TIP. In the display device 10, the cathode electrodes CE1, CE2, and CE3 may be individually formed in each of the different areas even in the deposition process that does not use the mask by the tips TIP of the bank structure BNS.

In an embodiment, capping layers CPL may be disposed on the cathode electrodes CE1, CE2, and CE3. The capping layers CPL may include an inorganic insulating material and cover the light emitting elements ED1, ED2, and ED3 and the patterns disposed on the bank structure BNS. The capping layers CPL may prevent damage to the light emitting elements ED1, ED2, and ED3 from external air, and prevent the patterns disposed on the bank structure BNS from being peeled off during the manufacturing process of the display device 10. In an embodiment, the capping layer CPL may include aluminum oxide, titanium oxide, tantalum oxide, hafnium oxide, zinc oxide, silicon oxide, silicon nitride, and/or silicon oxynitride.

In an embodiment, the display device 10 may include capping patterns CLP disposed above the bank structure BNS. The capping patterns CLP may be directly disposed on the first electrode pattern CEP1, the second electrode pattern CEP2, and the third electrode pattern CEP3 disposed on the second bank layer BN2 of the bank structure BNS. An arrangement relationship between the capping patterns CLP and the electrode patterns CEP1, CEP2, and CEP3 may be the same as an arrangement relationship between the cathode electrodes CE1, CE2, and CE3 of the light emitting elements ED1, ED2, and ED3, respectively, and the capping layers CPL. Such capping patterns CLP may be traces formed while the deposited materials are disconnected from the capping layers CPL rather than being connected to the capping layers CPL because the bank structure BNS includes the tips TIP.

In an embodiment, the plurality of organic patterns ELP1, ELP2, and ELP3, the electrode patterns CEP1, CEP2, and CEP3, and the capping patterns CLP may be disposed on the bank structure BNS, and may be disposed to surround the emission areas EA1, EA2, and EA3 or the openings OPE1, OPE2, and OPE3. Stacked structures of the organic patterns ELP1, ELP2, and ELP3, the electrode patterns CEP1, CEP2, and CEP3, and the capping patterns CLP disposed around the emission areas EA1, EA2, and EA3, respectively, may be partially etched in the manufacturing process of the display device 10, such that pattern shapes may be changed. Accordingly, portions of an upper surface of the second bank layer BN2 of the bank structure BNS may not be covered by the organic patterns ELP1, ELP2, and ELP3, the electrode patterns CEP1, CEP2, and CEP3, and the capping patterns CLP.

In an embodiment, the thin film encapsulation layer TFEL may be disposed on the light emitting elements ED1, ED2, and ED3 and the bank structure BNS, and may cover the plurality of light emitting elements ED1, ED2, and ED3 and the bank structure BNS. The thin film encapsulation layer TFEL may include at least one inorganic film to prevent oxygen or moisture from permeating into the light emitting element layer EML. The thin film encapsulation layer TFEL may include at least one organic film to protect the light emitting element layer EML from foreign substances such as dust.

In an embodiment, the thin film encapsulation layer TFEL may include a first encapsulation layer TFE1, a second encapsulation layer TFE2, and a third encapsulation layer TFE3 that are sequentially stacked. The first encapsulation layer TFEL and the third encapsulation layer TFE3 may be inorganic encapsulation layers, and the second encapsulation layer TFE2 disposed between the first encapsulation layer TFEL and the third encapsulation layer TFE3 may be an organic encapsulation layer.

In an embodiment, each of the first encapsulation layer TFEL and the third encapsulation layer TFE3 may include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

In an embodiment, the second encapsulation layer TFE2 may include a polymer-based material. The polymer-based material may include an acrylic resin, an epoxy-based resin, polyimide, polyethylene, and the like. For example, the second encapsulation layer TFE2 may include an acrylic resin such as polymethyl methacrylate or polyacrylic acid. The second encapsulation layer TFE2 may be formed by curing a monomer or applying a polymer.

In an embodiment, the first encapsulation layer TFE1 may be disposed on the light emitting elements ED1, ED2, and ED3, a plurality of patterns, and the bank structure BNS. The first encapsulation layer TFE1 may include the first inorganic layer TL1, the second inorganic layer TL2, and the third inorganic layer TL3 disposed to correspond respectively to the different emission areas EA1, EA2, and EA3, respectively.

In an embodiment, the first inorganic layer TL1, the second inorganic layer TL2, and the third inorganic layer TL3 may include an inorganic insulating material and cover the light emitting elements ED1, ED2, and ED3, respectively. The first inorganic layer TL1, the second inorganic layer TL2, and the third inorganic layer TL3 may prevent damage to the light emitting elements ED1, ED2, and ED3, respectively, from external air and prevent the patterns disposed on the bank structure BNS from being peeled off during the manufacturing process of the display device 10. In an embodiment, the first inorganic layer TL1, the second inorganic layer TL2, and the third inorganic layer TL3 may include aluminum oxide, titanium oxide, tantalum oxide, hafnium oxide, zinc oxide, silicon oxide, silicon nitride, and/or silicon oxynitride.

In an embodiment, the first inorganic layer TL1, the second inorganic layer TL2, and the third inorganic layer TL3 may be disposed to cover the organic patterns ELP1, ELP2, and ELP3, respectively, the electrode patterns CEP1, CEP2, and CEP3, respectively, and the capping patterns CLP. The first inorganic layer TL1, the second inorganic layer TL2, and the third inorganic layer TL3 may be formed through chemical vapor deposition (CVD), and may thus be formed at a uniform thickness along steps of layers on which they are deposited. For example, the first inorganic layer TL1, the second inorganic layer TL2, and the third inorganic layer TL3 may form thin films even under the undercuts by the tips TIP of the bank structure BNS.

In an embodiment, the first inorganic layer TL1 may be disposed on the first light emitting element ED1 and the first electrode pattern CEP1. The first inorganic layer TL1 may be disposed along the first light emitting element ED1 and an inner sidewall of the first opening OPE1 so as to cover the first light emitting element ED1 and the inner sidewall of the first opening OPE1, and may also be disposed to cover the first organic pattern ELP1, the first electrode pattern CEP1, and the capping pattern CLP. However, the first inorganic layer TL1 may not overlap the second opening OPE2 and the third opening OPE3, and may be disposed only in the first opening OPEL and on the bank structure BNS around the first opening OPE1.

In an embodiment, the second inorganic layer TL2 may be disposed on the second light emitting element ED2 and the second electrode pattern CEP2. The second inorganic layer TL2 may be disposed along the second light emitting element ED2 and an inner sidewall of the second opening OPE2 so as to cover the second light emitting element ED2 and the inner sidewall of the second opening OPE2, and may also be disposed to cover the second organic pattern ELP2, the second electrode pattern CEP2, and the capping pattern CLP. However, the second inorganic layer TL2 may not overlap the first opening OPE1 and the third opening OPE3, and may be disposed only in the second opening OPE2 and on the bank structure BNS around the second opening OPE2.

In an embodiment, the third inorganic layer TL3 may be disposed on the third light emitting element ED3 and the third electrode pattern CEP3. The third inorganic layer TL3 may be disposed along the third light emitting element ED3 and an inner sidewall of the third opening OPE3 so as to cover the third light emitting element ED3 and the inner sidewall of the third opening OPE3, and may also be disposed to cover the third organic pattern ELP3, the third electrode pattern CEP3, and the capping pattern CLP. However, the third inorganic layer TL3 may not overlap the first opening OPEL and the second opening OPE2, and may be disposed only in the third opening OPE3 and on the bank structure BNS around the third opening OPE3.

In an embodiment, the first inorganic layer TL1 may be formed after the first cathode electrode CE1 is formed, the second inorganic layer TL2 may be formed after the second cathode electrode CE2 is formed, and the third inorganic layer TL3 may be formed after the third cathode electrode CE3 is formed. Accordingly, the first to third inorganic layers TL1, TL2, and TL3, respectively, may be disposed to cover different electrode patterns CEP1, CEP2, and CEP3 and organic patterns ELP1, ELP2, and ELP3, respectively. Each of the first inorganic layer TL1, the second inorganic layer TL2, and the third inorganic layer TL3 may have a greater area than each of the openings OPE1, OPE2, and OPE3 of the bank structure BNS in a plan view. The first inorganic layer TL1, the second inorganic layer TL2, and the third inorganic layer TL3 may be disposed to be spaced apart from each other on the bank structure BNS. Accordingly, portions of the second bank layer BN2 of the bank structure BNS may not overlap the inorganic layers TL1, TL2, and TL3, and portions of the upper surface of the second bank layer BN2 of the bank structure BNS may be exposed without being covered by the inorganic layers TL1, TL2, and TL3. Portions of the second bank layer BN2 may be in direct contact with a second encapsulation layer TFE2 of a thin film encapsulation layer TFEL to be described later.

In an embodiment, the touch sensing layer TSU may be disposed on the thin film encapsulation layer TFEL. The touch sensing layer TSU may include a first touch insulating layer SIL1, a second touch insulating layer SIL2, touch electrodes TEL, and a third touch insulating layer SIL3.

In an embodiment, the first touch insulating layer SIL1 may be disposed on the thin film encapsulation layer TFEL. The first touch insulating layer SIL1 may have insulating and optical functions. The first touch insulating layer SIL1 may include at least one inorganic film. Optionally, the first touch insulating layer SIL1 may be omitted.

In an embodiment, the second touch insulating layer SIL2 may cover the first touch insulating layer SIL1. Although not illustrated in the drawings, touch electrodes of another layer may be further disposed on the first touch insulating layer SIL1, and the second touch insulating layer SIL2 may cover such touch electrodes TEL. The second touch insulating layer SIL2 may have insulating and optical functions. For example, the second touch insulating layer SIL2 may be an inorganic film including at least one of a silicon nitride layer, a silicon oxynitride layer, a silicon oxide layer, a titanium oxide layer, and an aluminum oxide layer.

In an embodiment, some of the touch electrodes TEL may be disposed on the second touch insulating layer SIL2. Each of the touch electrodes TEL may not overlap the first to third emission areas EA1, EA2, and EA3, respectively. Each of the touch electrodes TEL may be formed as a single layer made of molybdenum (Mo), titanium (Ti), copper (Cu), aluminum (Al), or indium tin oxide (ITO) or be formed as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO.

In an embodiment, the third touch insulating layer SIL3 may cover the touch electrodes TEL and the second touch insulating layer SIL2. The third touch insulating layer SIL3 may have insulating and optical functions. The third touch insulating layer SIL3 may be made of the material exemplified in the second touch insulating layer SIL2.

In an embodiment, the light blocking layer BM may be disposed on the touch sensing layer TSU. The light blocking layer BM may include the plurality of opening holes OPT1, OPT2, and OPT3 disposed to overlap the emission areas EA1, EA2, and EA3, respectively. For example, a first opening hole OPT1 may be disposed to overlap the first emission area EA1. A second opening hole OPT2 may be disposed to overlap the second emission area EA2, and a third opening hole OPT3 may be disposed to overlap the third emission area EA3. An area or a size of each of the opening holes OPT1, OPT2, and OPT3 may be greater than the area or the size of each of the emission areas EA1, EA2, and EA3 defined by the bank structure BNS. The opening holes OPT1, OPT2, and OPT3 of the light blocking layer BM are formed to be greater than the emission areas EA1, EA2, and EA3, respectively, and accordingly, the light emitted from the emission areas EA1, EA2, and EA3 may be viewed by a user not only from a front surface but also from side surfaces of the display device 10.

In an embodiment, the light blocking layer BM may include a light absorbing material. For example, the light blocking layer BM may include an inorganic black pigment or an organic black pigment. The inorganic black pigment may be carbon black, and the organic black pigment may include at least one of lactam black, perylene black, and aniline black, but the invention is not limited thereto. The light blocking layer BM may prevent color mixing due to permeation of visible light between the first to third emission areas EA1, EA2, and EA3 to improve a color gamut of the display device 10.

In an embodiment, the display device 10 may include a plurality of color filters CF1, CF2, and CF3 disposed on the emission areas EA1, EA2, and EA3, respectively. The plurality of color filters CF1, CF2, and CF3 may be disposed to correspond to the emission areas EA1, EA2, and EA3, respectively. For example, the color filters CF1, CF2, and CF3 may be disposed on the light blocking layer BM including the plurality of opening holes OPT1, OPT2, and OPT3 disposed to correspond to the emission areas EA1, EA2, and EA3, respectively. The opening holes of the light blocking layer may be formed to overlap the emission areas EA1, EA2, and EA3 or the openings of the bank structures BNS, and may form light emitting areas through which the light emitted from the emission areas EA1, EA2, and EA3 is emitted. Each of the color filters CF1, CF2, and CF3 may have a greater area than each of the opening holes of the light blocking layer BM, and each of the color filters CF1, CF2, and CF3 may completely cover the light emitting area formed by each of the opening holes.

In an embodiment, the color filters CF1, CF2, and CF3 may include a first color filter CF1, a second color filter CF2, and a third color filter CF3, respectively, disposed to correspond to the different emission areas EA1, EA2, and EA3, respectively. The color filters CF1, CF2, and CF3 may include colorants such as dyes or pigments absorbing light of wavelength bands other than light of a specific wavelength band, and may be disposed to correspond to the colors of the light emitting from the emission areas EA1, EA2, and EA3. For example, the first color filter CF1 may be a red color filter disposed to overlap the first emission area EA1 and transmitting only the first light, which is the red light, therethrough. The second color filter CF2 may be a green color filter disposed to overlap the second emission area EA2 and transmitting only the second light, which is the green light, therethrough, and the third color filter CF3 may be a blue color filter disposed to overlap the third emission area EA3 and transmitting only the third light, which is the blue light, therethrough.

In an embodiment, the plurality of color filters CF1, CF2, and CF3 may be spaced apart from other adjacent color filters CF1, CF2, and CF3 on the light blocking layer BM. The color filters CF1, CF2, and CF3 may have greater areas than the opening holes OPT1, OPT2, and OPT3 of the light blocking layer BM while covering the opening holes OPT1, OPT2, and OPT3 of the light blocking layer BM, respectively, but may have areas enough to be spaced apart from other color filters CF1, CF2, and CF3 on the light blocking layer BM. However, the invention is not limited thereto. The plurality of color filters CF1, CF2, and CF3 may be disposed to partially overlap other adjacent color filters CF1, CF2, and CF3. Different color filters CF1, CF2, and CF3 may overlap each other on a light blocking layer BM to be described later, which is an area that does not overlap the emission areas EA1, EA2, and EA3. In the display device 10, the color filters CF1, CF2, and CF3 are disposed to overlap each other, and accordingly, an intensity of reflected light by external light may be reduced. Furthermore, a color feeling of the reflected light by the external light may be controlled by adjusting arrangements, shapes, areas, and the like, of the color filters CF1, CF2, and CF3 in a plan view.

In an embodiment, the color filters CF1, CF2, and CF3 of the color filter layer CFL may be disposed on the light blocking layer BM. The different color filters CF1, CF2, and CF3 may be disposed to correspond to the different emission areas EA1, EA2, and EA3 or openings OPE1, OPE2, and OPE3 and the opening holes OPT1, OPT2, and OPT3 of the light blocking layer BM, respectively. For example, the first color filter CF1 may be disposed to correspond to the first emission area EA1, the second color filter CF2 may be disposed to correspond to the second emission area EA2, and the third color filter CF3 may be disposed to correspond to the third emission area EA3. The first color filter CF1 may be disposed in the first opening hole OPT1 of the light blocking layer BM, the second color filter CF2 may be disposed in the second opening hole OPT2 of the light blocking layer BM, and the third color filter CF3 is disposed in the third opening hole OPT3 of the light blocking layer BM. Each of the color filters CF1, CF2, and CF3 may be disposed to have a greater area than each of the opening holes OPT1, OPT2, and OPT3 of the light blocking layer BM in a plan view, and a portion of each of the color filters CF1, CF2, and CF3 may be directly disposed on the light blocking layer BM.

In an embodiment, an overcoat layer OC may be disposed on the color filters CF1, CF2, and CF3 to planarize upper ends of the color filters CF1, CF2, and CF3. The overcoat layer OC may be a colorless light transmitting layer that does not have a color of a visible light band. For example, the overcoat layer OC may include a colorless light transmitting organic material such as an acrylic resin.

In an embodiment, in the display device 10, the plurality of light emitting elements ED1, ED2, and ED3 disposed in the display area DA may be disposed in the emission areas EA1, EA2, and EA3 formed by the bank structures BNS, respectively. As described above, the cathode electrodes CE1, CE2, and CE3 of the respective light emitting elements ED1, ED2, and ED3 may be electrically connected to each other through the first bank layer BN1 of the bank structure BNS. The cathode electrodes CE1, CE2, and CE3 of the light emitting elements ED1, ED2, and ED3, respectively, and the first bank layer BN1 may form a common electrode in the display area DA.

Meanwhile, in an embodiment, in the display device 10, the bank structure BNS may be disposed up to the non-display area NDA beyond the display area DA. The first bank layer BN1 of the bank structure BNS may be disposed to extend to the non-display area NDA while forming the common electrode with the cathode electrodes CE1, CE2, and CE3 of the light emitting elements ED1, ED2, and ED3, respectively, and may be electrically connected to the first power line VL1 disposed in the non-display area NDA. Accordingly, the light emitting elements ED1, ED2, and ED3 may be electrically connected to the first power line VL1 disposed in the non-display area NDA, and may receive the low potential voltage through the first power line VL1.

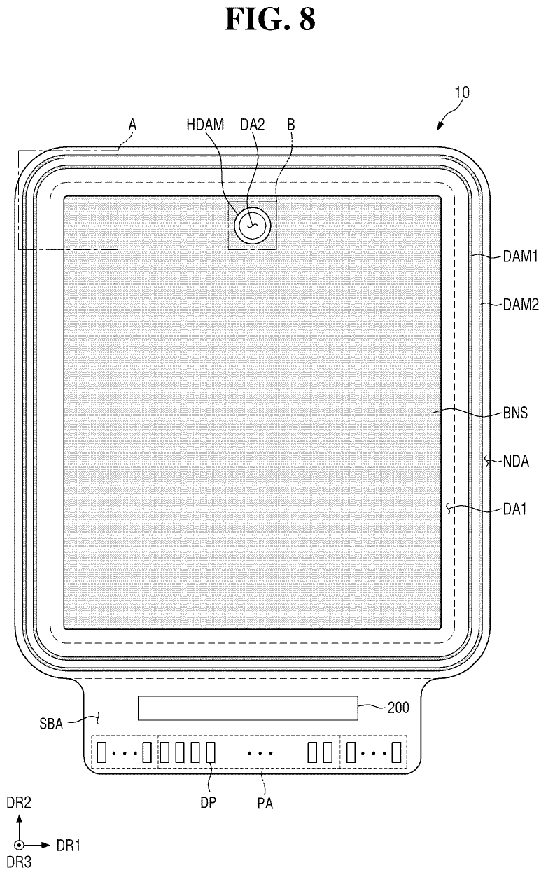

FIG. 8 is a plan view illustrating an arrangement of a dam structure disposed in the display device, according to an embodiment.

In an embodiment and referring to FIG. 8, the display layer DU of the display device 10 may include a display area DA and a non-display area NDA surrounding the display area DA. As described above with reference to FIG. 4, the plurality of pixels PX and the plurality of lines, for example, the second power lines VL2, the gate lines GL, and the data lines DL may be disposed in the display area DA. The display driver 200, the gate driver 210, the plurality of display pad parts DP, and the first power line VL1 may be disposed in the non-display area NDA. The first power line VL1 may be electrically connected to the plurality of pixels PX of the display area DA through the bank structure BNS.

In an embodiment, the first power line VL1 may be electrically connected to the first bank layer BN1 of the bank structure BNS, and may be electrically connected to the light emitting elements ED1, ED2, and ED3 through the first bank layer BN1 (scc FIG. 6). The cathode electrodes CE1, CE2, and CE3 of the light emitting elements ED1, ED2, and ED3 may form the common electrode with the first bank layer BN1 of the bank structure BNS, and may receive the low potential voltage transferred through the first power line VL1 (see FIG. 6). Although not illustrated in FIG. 8, the bank structure BNS may be disposed to extend to the non-display area NDA beyond the display area DA, and may be electrically connect to the first power line VL1 in the non-display area NDA. A connection between the first power line VL1 and the bank structure BNS will be described later with reference to other drawings.

According to an embodiment, the display device 10 may include a plurality of dams disposed in the non-display area NDA. The plurality of dams may include a first dam DAM1 surrounding the display area DA and spaced apart from the bank structure BNS disposed in the display area DA and a second dam DAM2 surrounding the first dam DAM1.

In an embodiment, the first dam DAM1 may be disposed to surround the display area DA and to be spaced apart from the bank structure BNS. The first dam DAM1 may surround the display area DA and the bank structure BNS by including portions extending in the first direction DR1 and the second direction DR2. The second dam DAM2 may be disposed to be spaced apart from the first dam DAM1. The second dam DAM2 may surround the display area DA and the first dam DAM1 by including portions extending in the first direction DR1 and the second direction DR2.

In an embodiment, the display device 10 may have a structure in which a plurality of layers are sequentially stacked on one substrate SUB. Some layers of the display device may be made of an organic material, and may be formed through a process in which the organic material is directly jetted onto the substrate SUB. For example, since the display device 10 includes the thin film encapsulation layer TFEL (see FIG. 6) and the second encapsulation layer TFE2 of the thin film encapsulation layer TFEL may include an organic material to flow with fluidity, the organic material jetted onto the display area DA may overflow into the non-display area NDA. The first dam DAM1 and the second dam DAM2 may prevent the organic material from overflowing into the outside of the non-display area NDA beyond the non-display area NDA.

In an embodiment, the plurality of dams DAM1 and DAM2 need to have a structure in which one or more layers are stacked and have a minimum thickness or height. The dams DAM1 and DAM2 may include a plurality of layers disposed in the display area DA and layers including the same material as the bank structure BNS to have heights enough to prevent the overflow of the organic material.

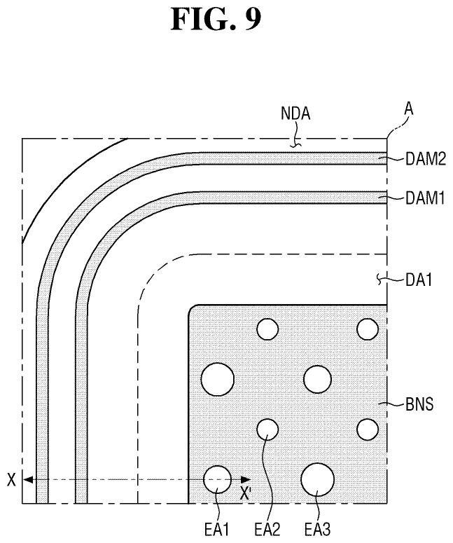

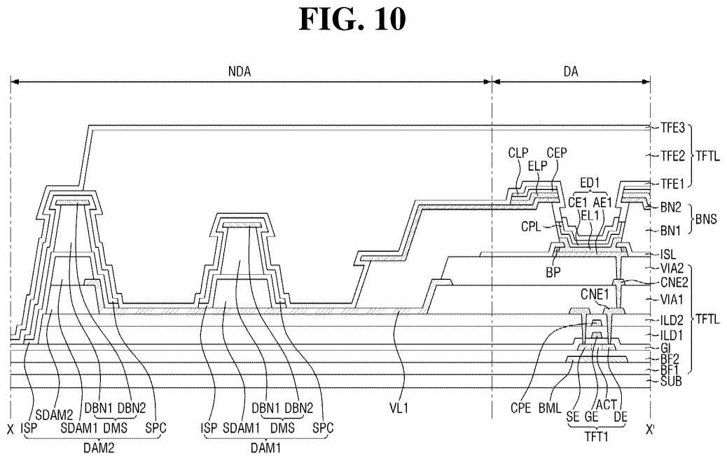

FIG. 9 is an enlarged view of portion A of FIG. 8, according to an embodiment. FIG. 10 is a cross-sectional view taken along line X-X′ of FIG. 9, according to an embodiment. In an embodiment, FIG. 9 illustrates an arrangement, in a plan view, of the bank structure BNS, the first dam DAM1, and the second dam DAM2 disposed adjacent to a corner portion of the display area DA. FIG. 10 illustrates a cross-section crossing the first dam DAM1, the second dam DAM2, and the emission area disposed in the opening of the bank structure BNS.

In an embodiment and referring to FIGS. 9 and 10, the bank structure BNS may include a plurality of openings disposed in the display area DA. As described above, the emission areas EA1, EA2, and EA3 may be formed by disposing the light emitting elements ED1, ED2, and ED3, respectively, in the openings.

According to an embodiment, the bank structure BNS may be disposed to extend from the display area DA to a partial area of the non-display area NDA. The bank structure BNS may overlap the first power line VL1. For example, the bank structure BNS may be directly disposed on and electrically connected to the first power line VL1 in the non-display area NDA. The first bank layer BN1 may be electrically connected to the first power line VL1 by including a metal material. Since the first bank layer BN1 forms the common electrode with the cathode electrodes CE of the light emitting elements ED, the first power line VL1 may be electrically connected to the light emitting elements ED through the first bank layer BN1.

In an embodiment, the first power line VL1 may be disposed in the non-display area NDA. Although not illustrated in the drawings, the first power line VL1 may have a predetermined width and extend in the second direction DR2 in the non-display area NDA. The first power line VL1 may include the same material as the second connection electrode CNE2 and may be disposed on the first via layer VIA1. However, an area in which the first via layer VIA1 and the second via layer VIA2 are not disposed may exist between the second dam DAM2 and the display area DA, and the first power line VL1 may be directly disposed on the second interlayer insulating layer ILD2.

According to an embodiment, each of the first dam DAM1 and the second dam DAM2 of the display device 10 may include a dam structure DMS having the same material and structure as the bank structure BNS. The dam structure DMS may include a first sub-dam structure DBN1 including the same material as the first bank layer BN1 and a second sub-dam structure DBN2 disposed on the first sub-dam structure DBN1 and including the same material as the second bank layer BN2. The first sub-dam structure DBN1 and the second sub-dam structure DBN2 may include aluminum (Al) and titanium (Ti), respectively, and the second sub-dam structure DBN2 may include tips protruding from side surfaces of the first sub-dam structure DBN1. A stacked structure of the first sub-dam structure DBN1 and the second sub-dam structure DBN2 may be substantially the same as a stacked structure of the first bank layer BN1 and the second bank layer BN2 of the bank structure BNS.

In an embodiment, the first dam DAM1 may include a first sub-dam SDAM1 and an insulating pattern ISP that are disposed between the dam structure DMS and the substrate SUB and a spacer SPC disposed on the dam structure DMS. The second dam DAM2 may include a first sub-dam SDAM1, a second sub-dam SDAM2, and an insulating pattern ISP that are disposed between the dam structure DMS and the substrate SUB and a spacer SPC disposed on the dam structure DMS. In the second dam DAM2, the second sub-dam SDAM2 may be positioned at the same height as the first via layer VIA1, and the first sub-dam SDAM1 may be positioned at the same height as the second via layer VIA2. In the first dam DAM1, the first sub-dam SDAM1 may be positioned at the same height as the first via layer VIA1.

In an embodiment, the first sub-dam SDAM1 of the first dam DAM1 may be directly disposed on the first power line VL1. The first sub-dam SDAM1 of the first dam DAM1 may include the same material as the second via layer VIA2, but may be positioned at the same height as the first via layer VIA1. The first sub-dam SDAM1 may not be electrically connected to the first power line VL1 by including an insulating material.

In an embodiment, the insulating pattern ISP of the first dam DAM1 may be disposed on the first sub-dam SDAM1. The insulating pattern ISP may be disposed to surround an outer surface of the first sub-dam SDAM1. The insulating pattern ISP may include the same material as the inorganic insulating layer ISL disposed in the display area DA. The insulating pattern ISP may be in partial contact with the first power line VL1, but may be electrically insulated from the first power line VL1.

In an embodiment, the dam structure DMS of the first dam DAM1 may be disposed on the insulating pattern ISP. The first sub-dam structure DBN1 of the dam structure DMS may be directly disposed on the insulating pattern ISP, and the second sub-dam structure DBN2 may be disposed on the first sub-dam structure DBN1. The first dam DAM1 may not include a layer including the same material as the first via layer VIA1, and the dam structure DMS may be positioned at a height similar to that of the second via layer VIA2.

In an embodiment, the spacer SPC of the first dam DAM1 may be disposed on the dam structure DMS. The spacer SPC may be disposed to cover outer surfaces of the dam structure DMS and the insulating pattern ISP. The spacer SPC may be disposed to fill lower portions of the tips formed by the second sub-dam structure DBN2 of the dam structure DMS.

In an embodiment, the second dam DAM2 may further include the second sub-dam SDAM2 as compared with the first dam DAM1. The second sub-dam SDAM2 of the second dam DAM2 may be directly disposed on the second interlayer insulating layer ILD2. The second sub-dam SDAM2 may include the same material as the first via layer VIA1 and may be positioned at the same height as the first via layer VIA1.

In an embodiment, the first sub-dam SDAM1 of the second dam DAM2 may be disposed on the second sub-dam SDAM2. The second sub-dam SDAM2 of the second dam DAM2 may include the same material as the second via layer VIA2 and may be positioned at the same height as the second via layer VIA2.

In an embodiment, the insulating pattern ISP of the second dam DAM2 may be disposed on the first sub-dam SDAM1. The insulating pattern ISP may be disposed to surround outer surfaces of the first sub-dam SDAM1 and the second sub-dam SDAM2. A portion of the insulating pattern ISP may be disposed at the outermost portion of the non-display area NDA, and the insulating pattern ISP may also be disposed on the first interlayer insulating layer ILD1, the second interlayer insulating layer ILD2, and the second buffer layer BF2.

In an embodiment, the dam structure DMS of the second dam DAM2 may be disposed on the insulating pattern ISP. The first sub-dam structure DBN1 of the dam structure DMS may be directly disposed on the insulating pattern ISP, and the second sub-dam structure DBN2 may be disposed on the first sub-dam structure DBN1. The dam structure DMS of the second dam DAM2 may be positioned at the same height as the bank structure BNS.

In an embodiment, the spacer SPC of the second dam DAM2 may be disposed on the dam structure DMS. The spacer SPC may be disposed to cover outer surfaces of the dam structure DMS and the insulating pattern ISP. The spacer SPC may be disposed to fill lower portions of the tips formed by the second sub-dam structure DBN2 of the dam structure DMS.

In an embodiment, a height of the first dam DAM1 may be lower than a height of the second dam DAM2. The first dam DAM1 does not include the second sub-dam SDAM2 unlike the second dam DAM2, and may thus have a relatively low height.

In an embodiment, the display device 10 includes the inorganic insulating layer ISL disposed in the display area DA, and thus, a height of an organic material layer disposed in the non-display area NDA may be low. However, in the display device 10, the dam structures DMS including the same material as the bank structure BNS and having the same structure as the bank structure BNS constitute portions of the dams DAM1 and DAM2 in the non-display area NDA, and thus, the dams DAM1 and DAM2 may have heights enough to prevent the overflow of the organic material.

In an embodiment, the first encapsulation layer TFEL and the third encapsulation layer TFE3 may cover the first dam DAM1 and the second dam DAM2 disposed at the outermost portion of the display area DA. The first encapsulation layer TFEL and the third encapsulation layer TFE3 may extend to the outermost edge of the display panel 100 beyond the first dam DAM1 and the second dam DAM2.

In an embodiment, the second encapsulation layer TFE2 may be disposed to cover the first dam DAM1 and not to cover an upper surface of the second dam DAM2. However, the Invention is not limited thereto. The second encapsulation layer TFE2 may not cover both an upper surface of the first dam DAM1 and the upper surface of the second dam DAM2. The second encapsulation layer TFE2 may not overflow to an edge of the display panel 100 due to the first dam DAM1 and the second dam DAM2.

In an embodiment, the first interlayer insulating layer ILD1, the second interlayer insulating layer ILD2, the first via layer VIA1, and the second via layer VIA2 of the thin film transistor layer TFTL may be removed outside the second dam DAM2. Only the buffer layers BF1 and BF2 of the thin film transistor layer TFTL may be disposed outside the second dam DAM2, and the first encapsulation layer TFE1 and the third encapsulation layer TFE3 extending to the outermost edge of the display panel 100 may be directly disposed on the second buffer layer BF2.

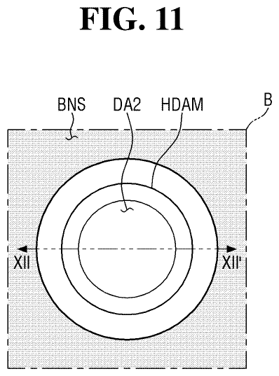

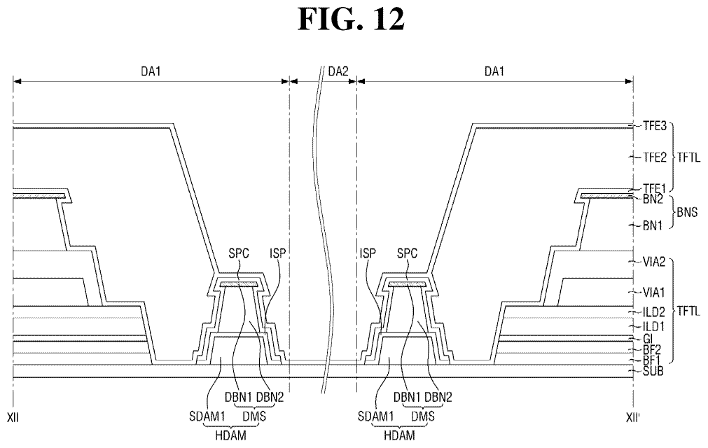

FIG. 11 is an enlarged view of portion B of FIG. 8, according to an embodiment. FIG. 12 is a cross-sectional view taken along line XII-XII′ of FIG. 11, according to an embodiment. In an embodiment, FIG. 11 illustrates an arrangement, in a plan view, of the second display area DA2 and a hole dam HDAM disposed around the second display area DA2. FIG. 12 illustrates a cross section crossing the second display area DA2.

Referring to FIGS. 11 and 12, the display device 10 according to an embodiment may include the hole dam HDAM surrounding the second display area DA2. Emission areas may not be partially formed in the second display area DA2 unlike the first display area DA1 (see FIG. 8). The second display area DA2 is an area in which the optical device 500 is disposed there below, and may be an area through which light is transmitted. The hole dam HDAM may prevent organic materials disposed in the first display area DA1 from overflowing into the second display area DA2 while dividing the first display area DA1 and the second display area DA2 within the display area DA.

According to an embodiment, the display device 10 may include the hole dam HDAM including a dam structure DMS including the same material as the bank structure BNS and having the same structure as the bank structure BNS. The hole dam HDAM may have the same structure as the first dam DAM1. For example, the hole dam HDAM may include a first sub-dam SDAM1, an insulating pattern ISP, the dam structure DMS, and a spacer SPC. In the second display area DA2, the upper surface of the substrate SUB may be exposed, and the hole dam HDAM may be directly disposed on the substrate SUB. A description of a stacked structure of the hole dam HDAM is the same as that of the stacked structure of the first dam DAM1 described above.

In an embodiment, the first encapsulation layer TFE1 and the third encapsulation layer TFE3 of the thin film encapsulation layer TFEL may also be disposed in the second display area DA2 beyond the hole dam HDAM, but the second encapsulation layer TFE2 may be disposed so as not to go beyond the hole dam HDAM. The display device 10 may prevent the organic material from overflowing into the second display area DA2 by including the hole dam HDAM dividing the first display area DA1 and the second display area DA2.

Hereinafter, various embodiments of the display device 10 will be described with reference to other drawings.

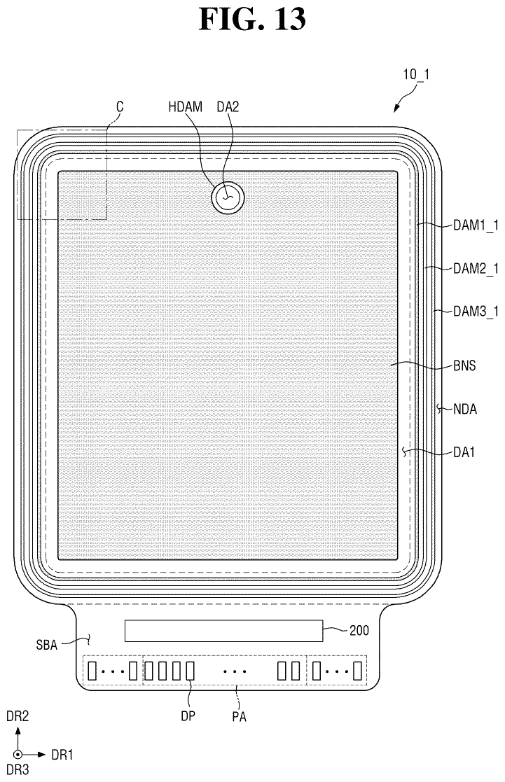

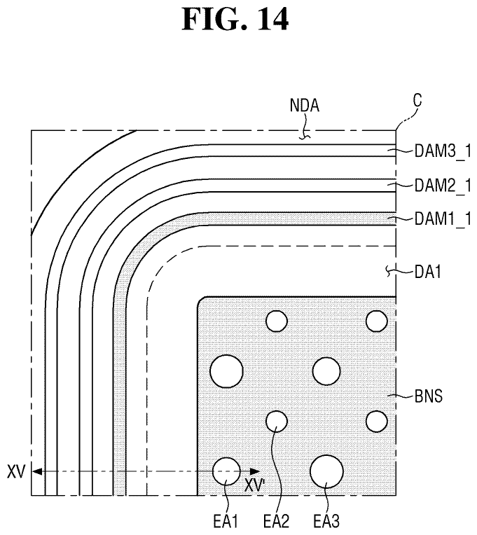

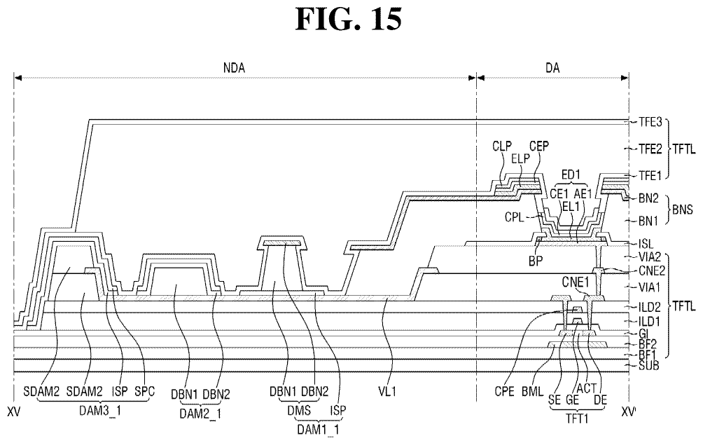

FIG. 13 is a plan view illustrating an arrangement of a dam structure disposed in a display device, according to another embodiment. FIG. 14 is an enlarged view of portion C of FIG. 13, according to another embodiment. FIG. 15 is a cross-sectional view taken along line XV-XV′ of FIG. 14, according to another embodiment.

Referring to FIGS. 13 to 15, a display device 10_1 according to another embodiment may include a first dam DAM1_1, a second dam DAM2_1, and a third dam DAM3_1 disposed in the non-display area NDA. The first dam DAM1_1 may be disposed to surround the display area DA, the second dam DAM2_1 may be disposed to surround the first dam DAM1_1, and the third dam DAM3_1 may be disposed to surround the second dam DAM2_1. The display device 10_1 may include a greater number of dams DAM than the display device according to the above-described embodiment.

According to another embodiment, the first dam DAM1_1 may include sub-dam structures DBN1 and DBN2 including the same materials as the bank layers BN1 and BN2 of the bank structure BNS, while the second dam DAM2_1 and the third dam DAM3_1 may not include sub-dam structures DBN1 and DBN2. For example, the first dam DAM1_1 may include a first sub-dam structure DBN1 disposed adjacent to the display area DA and disposed on the first power line VL1 and a second sub-dam structure DBN2 disposed on the first sub-dam structure DBN1. The first sub-dam structure DBN1 and the second sub-dam structure DBN2 may include the same materials as the first bank layer BN1 and the second bank layer BN2 of the bank structure BNS, respectively. The first dam DAM1_1 may further include an insulating pattern ISP disposed on the first power line VL1, and the first sub-dam structure DBN1 and the second sub-dam structure DBN2 may be disposed on the insulating pattern ISP. The first dam DAM1_1 may include the same material as the bank structure BNS and have the same structure as the bank structure BNS, but may be positioned at the same height as the second via layer VIA2 of the display area DA.

In an embodiment, the second dam DAM2_1 may include a first sub-dam SDAM1, an insulating pattern ISP, and a spacer SPC. The second dam DAM2_1 may have a structure in which the first sub-dam SDAM1 is directly disposed on the first power line VL1 and an insulation pattern ISP and a spacer SPC are sequentially stacked on the first sub-dam SDAM1. The first sub-dam SDAM1 of the second dam DAM2_1 may include the same material as the second via layer VIA2 as described above, but may be positioned at the same height as the first via layer VIA1 of the display area DA.

In an embodiment, the third dam DAM3_1 may include a first sub-dam SDAM1, a second sub-dam SDAM2, an insulating pattern ISP, and a spacer SPC. The third dam DAM3_1 may have a structure in which the second sub-dam SDAM2 is directly disposed on the first power line VL1 and the first sub-dam SDAM1, the insulating pattern ISP, and the spacer SPC are sequentially stacked on the second sub-dam SDAM2. As described above, the second sub-dam SDAM2 of the third dam DAM3_1 may include the same material as the first via layer VIA1, and the first sub-dam SDAM1 of the third dam DAM3_1 may include the same material as the second via layer VIA2. The second sub-dam SDAM2 and the first sub-dam SDAM1 of the third dam DAM3_1 may be positioned at the same heights as the first via layer VIA1 and the second via layer VIA2, respectively.

The display device 10_1 according to another embodiment may include the first dam DAM1_1 having the same structure as the bank structure BNS and disposed so as not to overlap the other sub-dams SDAM1 and SDAM2, and may further include the second dam DAM2_1 and the third dam DAM3_1 in which layers having structures different from those of the bank structure BNS are stacked. The display device 10_1 according to another embodiment may prevent the overflow of the organic materials by including dams DAM1_1, DAM2_1, and DAM3_1 of which heights are lower than heights of the dams of the display device according to an embodiment of FIG. 10, but the number is greater than the number of dams of the display device according to an embodiment of FIG. 10.

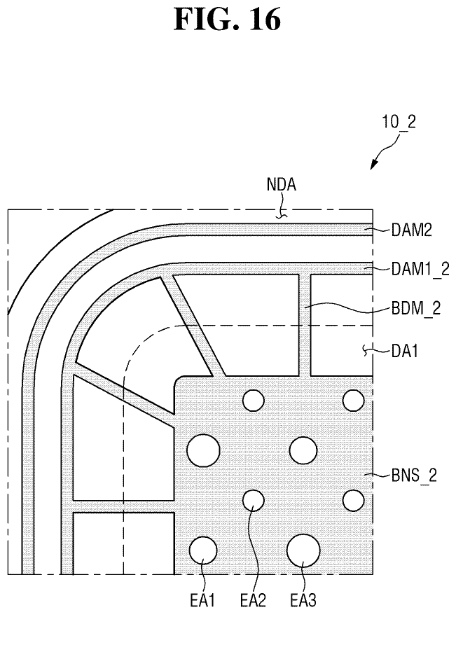

FIG. 16 is a schematic view illustrating portions of a bank structure and a dam structure of a display device, according to another embodiment.

Referring to FIG. 16, in a display device 10_2 according to another embodiment, a first dam DAM1_2 and a bank structure BNS_2 may be connected to each other through a dam connection part BDM_2. As described above, each of the first dam DAM1_2 and the second dam DAM2 may include a dam structure DMS having the same structure as the bank structure BNS_2. In the first dam DAM1_2 to which the bank structure BNS_2 is relatively adjacent, the dam structure DMS may be integrated with the bank structure BNS_2. For example, the dam structure DMS of the first dam DAM1_2 may be connected to the bank structure BNS_2 through the dam connection part BDM_2. Although not illustrated in FIG. 16, the dam structure DMS and the dam connection part BDM_2 may include a first sub-dam structure DBN1 and a second sub-dam structure DBN2, respectively. The first sub-dam structure DBN1 and the second sub-dam structure DBN2 may be disposed at the same layers as the first bank layer BN1 and the second bank layer BN2, respectively, and may be integrated with the first bank layer BN1 and the second bank layer BN2, respectively.

In an embodiment, in the display device 10_2, each of the bank structure BNS_2 disposed in the display area DA and the dam structure DMS disposed in the non-display area NDA may include a metal material to have electrical conductivity. The dam structure DMS may be covered by the spacer SPC and the thin film encapsulation layer TFEL, but static electricity may be generated due to conductivity of the dam structure DMS. In the display device 10_2, the dam structure DMS of the first dam DAM1_2 disposed in the non-display area NDA may be connected to the bank structure BNS_2 in the display area DA, and the generation of the static electricity may be prevented through electrical connection between the dam structure DMS of the first dam DAM1_2 and the bank structure BNS_2.

While the invention has been particularly shown and described with reference to embodiments thereof, it will be understood by those of ordinary skill in the art that various changes in form and details may be made therein without departing from the spirit or scope of the invention as defined by the following claims. The invention should not be construed as being limited to the embodiments set forth herein. Rather, these embodiments are provided so that this disclosure will be thorough and complete and will fully convey the concept of the invention to those skilled in the art. Moreover, the embodiments or parts of the embodiments may be combined in whole or in part without departing from the scope of the invention.

What is claimed is:

1. A display device comprising:
a substrate including a display area and a non-display area surrounding the display area;
a bank structure disposed on the substrate in the display area and including a plurality of openings;
a plurality of light emitting elements disposed in the plurality of openings;
a first dam disposed on the substrate in the non-display area and spaced apart from the bank structure; and
a second dam spaced apart from the first dam in the non-display area,
wherein the bank structure includes a first bank layer and a second bank layer disposed on the first bank layer and including a metal material different from that of the first bank layer,
wherein the first dam includes a first sub-dam structure including the same material as the first bank layer and a second sub-dam structure disposed on the first sub-dam structure and including the same material as the second bank layer, and
wherein the second bank layer includes tips protruding from sidewalls of the first bank layer, and the second sub-dam structure includes tips protruding from sidewalls of the first sub-dam structure.

2. The display device of claim 1, wherein the first dam further includes a first sub-dam, and
wherein the first sub-dam structure is disposed on the first sub-dam.

3. The display device of claim 2, wherein the first dam further includes an insulating pattern disposed on the first sub-dam and a spacer disposed on the second sub-dam structure,
wherein the insulating pattern is disposed to surround the first sub-dam, and
the spacer is disposed to cover outer surfaces of the insulating pattern, the first sub-dam structure, and the second sub-dam structure.

4. The display device of claim 2, wherein the second dam includes the same layers as the first sub-dam, the first sub-dam structure, and the second sub-dam structure, and
wherein the second dam further includes a second sub-dam disposed below the first sub-dam.

5. The display device of claim 4, further comprising a first via layer disposed between the bank structure and the substrate in the display area, and a second via layer disposed on the first via layer,
wherein the first sub-dam includes the same material as the second via layer, and
the second sub-dam includes the same material as the first via layer.

6. The display device of claim 2, wherein the display area includes a first display area and a second display area surrounded by the first display area, and
wherein the display device further comprises a hole dam disposed to surround the second display area.

7. The display device of claim 6, wherein the hole dam is spaced apart from the bank structure and includes the first sub-dam structure and the second sub-dam structure.

8. The display device of claim 2, further comprising a bank connection part connecting the first dam to the bank structure.

9. The display device of claim 1, wherein the first dam further includes an insulating pattern, and
wherein the first sub-dam structure is directly disposed on the insulating pattern.

10. The display device of claim 9, further comprising a third dam disposed to be spaced apart from the second dam,
wherein the second dam includes a first sub-dam and a spacer disposed on the first sub-dam, and
wherein the third dam includes the first sub-dam, a second sub-dam disposed below the first sub-dam, and a spacer disposed on the first sub-dam.

11. The display device of claim 1, wherein the first bank layer and the first sub-dam structure include aluminum (Al), and
wherein the second bank layer and the second sub-dam structure include titanium (Ti).

12. The display device of claim 11, wherein each of the plurality of light emitting elements include an anode electrode disposed to overlap the plurality of openings, a light emitting layer disposed on the anode electrode, and a cathode electrode disposed on the light emitting layer, and
wherein the cathode electrode is in contact with side surfaces of the first bank layer.

13. The display device of claim 12, further comprising:
an organic pattern disposed around the plurality of openings on the second bank layer and including the same material as the light emitting layer;
an electrode pattern disposed on the organic pattern and including the same material as the cathode electrode; and
an inorganic layer disposed to cover the plurality of light emitting elements and the electrode pattern.

14. The display device of claim 1, further comprising a first power line disposed in the non-display area,
wherein the first dam is disposed on the first power line, and the bank structure is in contact with the first power line.

15. A display device comprising:
a display area and a non-display area disposed around the display area;
a bank structure disposed in the display area and including a plurality of openings in which a plurality of light emitting elements are disposed;
a first dam disposed in the non-display area, spaced apart from the bank structure, and disposed to surround the bank structure; and
a second dam spaced apart from the first dam in the non-display area and disposed to surround the first dam,
wherein the bank structure includes a first bank layer and a second bank layer disposed on the first bank layer and including a metal material different from that of the first bank layer,
wherein the first dam includes a dam structure including a first sub-dam structure including the same material as the first bank layer and a second sub-dam structure including the same material as the second bank layer and disposed on the first sub-dam structure,
wherein the second bank layer includes tips protruding from sidewalls of the first bank layer, and
the second sub-dam structure includes tips protruding from sidewalls of the first sub-dam structure.

16. The display device of claim 15, wherein the first dam further includes a first sub-dam overlapping the dam structure, and
wherein the second dam includes the dam structure and the first sub-dam and further includes a second sub-dam overlapping the first sub-dam.

17. The display device of claim 16, wherein each of the first dam and the second dam further includes an insulating pattern overlapping the first sub-dam and a spacer disposed on the dam structure.

18. The display device of claim 15, wherein the display area includes a first display area and a second display area surrounded by the first display area, and
wherein the display device further comprises a hole dam surrounding the second display area, disposed to be spaced apart from the bank structure, and including the dam structure.

19. The display device of claim 15, wherein the second dam includes a first sub-dam, and
wherein the display device further comprises a third dam disposed to be spaced apart from the second dam, surrounding the second dam, and including the first sub-dam and a second sub-dam overlapping the first sub-dam.

20. The display device of claim 19, wherein the first sub-dam of the second dam and the first sub-dam of the third dam include the same material.
